(19) United States
(12) Patent Application Publication
(10) Pub. No.: US 2026/0011691 A1
(43) Pub. Date: Jan. 8, 2026

(54) SEMICONDUCTOR PACKAGE

(71) Applicant: SAMSUNG ELECTRONICS CO., LTD., Suwon-si (KR)

(72) Inventors: Jiyoung PARK, Suwon-si (KR); Unbyoung KANG, Suwon-si (KR); Jeonggi JIN, Suwon-si (KR)

(21) Appl. No.: 19/025,456

(22) Filed: Jan. 16, 2025

(30) Foreign Application Priority Data
Jul. 4, 2024 (KR) 10-2024-0088508

(51) Int. Cl. H01L 25/065; H01L 21/56; H01L 23/00; H01L 23/31; H01L 23/538; H10B 80/00

(52) U.S. Cl. CPC H01L 25/0657; H01L 23/3128; H01L 23/5386; H01L 24/14; H01L 24/16; H01L 24/32; H01L 24/73; H01L 21/565; H01L 24/13; H01L 2224/13111; H01L 2224/13116; H01L 2224/13124; H01L 2224/13139; H01L 2224/13144; H01L 2224/13147; H01L 2224/13155; H01L 2224/13166; H01L 2224/1403; H01L 2224/14135; H01L 2224/16225; H01L 2224/32145; H01L 2224/73203; H01L 2224/73253; H01L 2225/06517; H01L 2225/06562; H01L 2924/1436; H10B 80/00

(57) ABSTRACT

A semiconductor package includes a redistribution structure, a first semiconductor chip above the redistribution structure, a second semiconductor chip on, and offset relative to, the first semiconductor chip, a plurality of first conductive posts extending from a bottom surface of the second semiconductor chip to a top surface of the redistribution structure, a third semiconductor chip on the second semiconductor chip, a plurality of second conductive posts extending from a bottom surface of the third semiconductor chip to the top surface of the redistribution structure, and a molding layer between the top surface of the redistribution structure and the bottom surface of the third semiconductor chip.

### CROSS-REFERENCE TO RELATED APPLICATION

This application is based on and claims priority under 35 U.S.C. § 119 to Korean Patent Application No. 10-2024-0088508, filed on Jul. 4, 2024, in the Korean Intellectual Property Office, the disclosure of which is incorporated by reference herein in its entirety.

### BACKGROUND

The inventive concept relates to a semiconductor package, and more particularly, to a semiconductor package including a plurality of stacked semiconductor chips.

Recently, in accordance with the rapid development of the electronics industry and user demands, electronic devices have become more compact, multi-functional, and large in capacity, which requires highly integrated semiconductor chips. Accordingly, a semiconductor package is being designed including highly integrated semiconductor chips with an increased number of input/output (I/O) connection terminals while ensuring connection reliability.

### SUMMARY

The inventive concept provides a semiconductor package that suppresses cracks occurring on each of multiple semiconductor chips.

The inventive concept also provides a semiconductor package with low production cost and low process difficulty.

In addition, the inventive concept is not limited to the mentioned above, and other inventive concepts not mentioned are clearly understood by those skilled in the art from the description below.

According to an aspect of the inventive concept, there is provided a semiconductor package including a redistribution structure including a redistribution pattern and a redistribution insulating layer surrounding the redistribution pattern, a first semiconductor chip above the redistribution structure, a second semiconductor chip on, and offset relative to, the first semiconductor chip, a plurality of first conductive posts extending from a bottom surface of the second semiconductor chip to a top surface of the redistribution structure, wherein the plurality of first conductive posts are spaced apart from the first semiconductor chip, a third semiconductor chip on the second semiconductor chip, a plurality of second conductive posts extending from a bottom surface of the third semiconductor chip to the top surface of the redistribution structure, wherein the plurality of second conductive posts are spaced apart from the first semiconductor chip and the second semiconductor chip, and a molding layer between the top surface of the redistribution structure and the bottom surface of the third semiconductor chip, wherein the molding layer surrounds the first semiconductor chip, the second semiconductor chip, the plurality of first conductive posts, and the plurality of second conductive posts.

According to another aspect of the inventive concept, there is provided a semiconductor package including a redistribution structure including a redistribution pattern and a redistribution insulating layer surrounding the redistribution pattern, a first semiconductor chip on the redistribution structure, a plurality of conductive pillars extending from a bottom surface of the first semiconductor chip to a top surface of the redistribution structure, a first molding layer on the redistribution structure, wherein the first molding layer surrounds the first semiconductor chip and the plurality of conductive pillars, a second semiconductor chip above the first molding layer and offset relative to the first semiconductor chip, a plurality of first conductive posts extending from a bottom surface of the second semiconductor chip to the top surface of the redistribution structure, wherein the plurality of first conductive posts are spaced apart from the first semiconductor chip, a third semiconductor chip on the second semiconductor chip, a plurality of second conductive posts extending from a bottom surface of the third semiconductor chip to the top surface of the redistribution structure, wherein the plurality of second conductive posts are spaced apart from the first semiconductor chip and the second semiconductor chip, and a second molding layer between a top surface of the first molding layer and the bottom surface of the third semiconductor chip, wherein the second molding layer surrounds the second semiconductor chip, a portion of each of the plurality of first conductive posts, and a portion of each of the plurality of second conductive posts.

According to another aspect of the inventive concept, there is provided a semiconductor package including a redistribution structure including a redistribution pattern and a redistribution insulating layer surrounding the redistribution pattern, a first semiconductor chip above the redistribution structure, a plurality of conductive pillars extending from a bottom surface of the first semiconductor chip to a top surface of the redistribution structure, a first adhesive layer on a top surface of the first semiconductor chip, a second semiconductor chip above the first semiconductor chip and offset relative to the first semiconductor chip, a plurality of first conductive posts extending from a bottom surface of the second semiconductor chip to the top surface of the redistribution structure, wherein the plurality of first conductive posts are spaced apart from the first semiconductor chip, a second adhesive layer on a top surface of the second semiconductor chip, a third semiconductor chip on the second semiconductor chip, wherein the third semiconductor chip includes a top surface having an area equal to an area of the top surface of the redistribution structure, a plurality of second conductive posts extending from a bottom surface of the third semiconductor chip to the top surface of the redistribution structure, wherein the plurality of second conductive posts are spaced apart from the first semiconductor chip and the second semiconductor chip, and a molding layer between the top surface of the redistribution structure and the bottom surface of the third semiconductor chip, wherein the molding layer surrounds the first semiconductor chip, the second semiconductor chip, the plurality of conductive pillars, the plurality of first conductive posts, and the plurality of second conductive posts, wherein a side surface of the redistribution structure, a side surface of the molding layer, and a side surface of the third semiconductor chip are coplanar, and wherein a number of the second conductive posts is greater than a number of the first conductive posts.

### BRIEF DESCRIPTION OF THE DRAWINGS

Embodiments will be more clearly understood from the following detailed description taken in conjunction with the accompanying drawings in which:

FIG. 1 is a schematic plan view of a semiconductor package according to an embodiment;

FIG. 2 is a schematic cross-sectional view of the semiconductor package of FIG. 1 taken along line A-A′ in FIG. 1;

FIG. 3 is a schematic cross-sectional view of a semiconductor package according to an embodiment;

FIG. 4 is a schematic plan view of a semiconductor package according to an embodiment;

FIG. 5 is a schematic plan view of a semiconductor package according to an embodiment;

FIG. 6 is a schematic plan view of a semiconductor package according to an embodiment;

FIGS. 7A to 7L are diagrams illustrating a method of manufacturing a semiconductor package according to a process sequence, according to an embodiment; and

FIGS. 8A to 8N are diagrams illustrating a method of manufacturing a semiconductor package according to a process sequence, according to an embodiment.

### DETAILED DESCRIPTION OF THE EMBODIMENTS

Since the embodiments are subject to various changes and have various forms, some embodiments may be illustrated in the drawings and described in detail. However, this is not intended to limit the embodiments to the specific disclosure form.

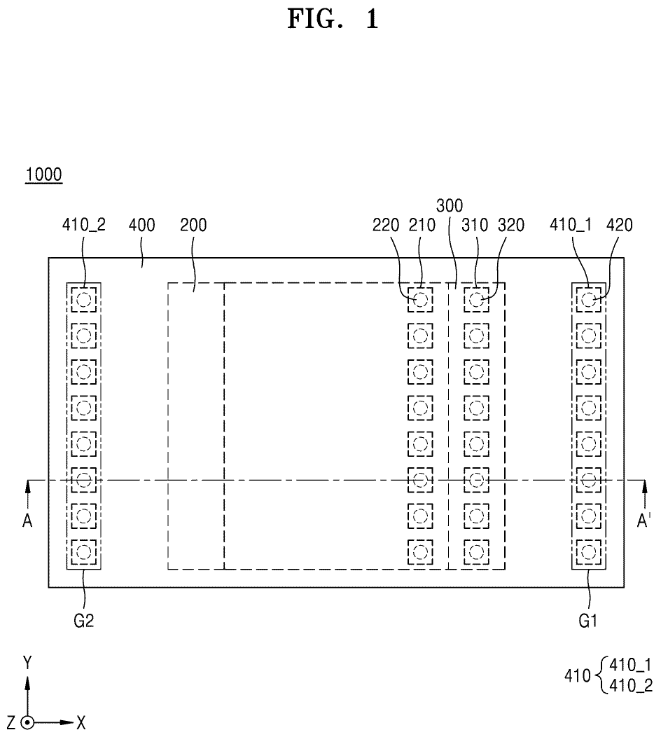

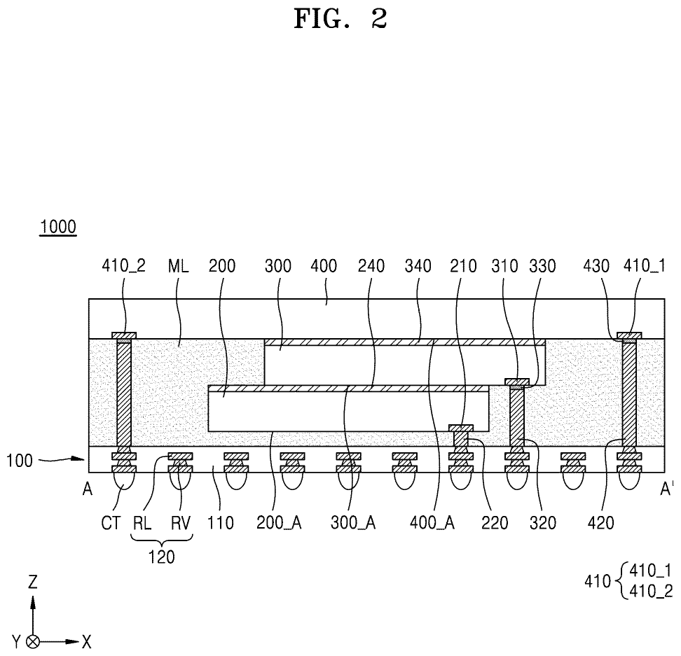

FIG. 1 is a schematic plan view of a semiconductor package 1000 according to an embodiment. FIG. 2 is a schematic cross-sectional view of the semiconductor package 1000 of FIG. 1 taken along line A-A′ in FIG. 1.

Referring to FIGS. 1 and 2, the semiconductor package 1000 may include a redistribution structure 100, a first semiconductor chip 200, a plurality of conductive pillars 220, a second semiconductor chip 300, a plurality of first conductive posts 320, a third semiconductor chip 400, a plurality of second conductive posts 420, and a molding layer ML.

Hereinafter, unless otherwise specified, a direction parallel to a top surface of the redistribution structure 100 is defined as a first horizontal direction (X direction), a direction perpendicular to the top surface thereof is defined as a vertical direction (Z direction), and a direction perpendicular to each of the first horizontal direction (X direction) and the vertical direction (Z direction) is defined as a second horizontal direction (Y direction). A horizontal direction is defined as a combined direction of the first horizontal direction (X direction) and the second horizontal direction (Y direction).

The redistribution structure 100 may include redistribution patterns 120 and a redistribution insulating layer 110 surrounding the redistribution patterns 120. The redistribution structure 100 may be electrically connected to the first semiconductor chip 200, the second semiconductor chip 300, and the third semiconductor chip 400. For example, the redistribution structure 100 may extend a plurality of first input/output terminals 210 of the first semiconductor chip 200 to the edge of the first semiconductor chip 200 and extend a plurality of second input/output terminals 310 of the second semiconductor chip 300 to the edge of the second semiconductor chip 300.

The redistribution pattern 120 may include a redistribution line RL extending in the horizontal direction and a redistribution via RV extending from the redistribution line RL in a third direction (e.g. the vertical direction). The redistribution line RL may be arranged on at least one of a top surface and a bottom surface of the redistribution insulating layer 110 or inside the redistribution insulating layer 110. The redistribution via RV may pass through the redistribution insulating layer 110 and may be connected to a portion of the redistribution line RL.

In some embodiments, the width of the redistribution via RV of the redistribution pattern 120 may decrease as the redistribution via RV approaches the top surface of the redistribution structure 100. For example, the width of the redistribution via RV of the redistribution pattern 120 may decrease as the redistribution via RV moves upward in the third direction (e.g. Z direction). For example, the redistribution via RV of the redistribution pattern 120 may decrease as the redistribution via RV approaches the first semiconductor chip 200.

The redistribution via RV may be completely filled with a conductive material or may have a shape in which the conductive material is formed along the wall of the redistribution via RV. The redistribution patterns 120 may include a conductive material, e.g., copper (Cu), aluminum (Al), silver (Ag), tin (Sn), gold (Au), nickel (Ni), lead (Pb), titanium (Ti), or an alloy thereof. The number and arrangement of redistribution vias RV and redistribution lines RL are not limited to those shown in the drawings and may vary in various embodiments.

The redistribution insulating layer 110 may include an insulating material, for example, a photo imageable dielectric (PID) resin. In this case, the redistribution insulating layer 110 may further include an inorganic filler. In some embodiments, the redistribution insulating layer 110 may have a multilayer structure in which the redistribution patterns 120 are arranged in each layer.

In some embodiments, external connection terminals CT may be attached to a bottom surface of the redistribution structure 100. The external connection terminals CT may be configured to electrically and physically connect the redistribution structure 100 to an external device on which the redistribution structure 100 is mounted. The external connection terminals CT may be formed, for example, from solder balls or solder bumps.

The first semiconductor chip 200 may be located above the redistribution structure 100. The first semiconductor chip 200 may be spaced apart from the redistribution structure 100 in the third direction (e.g. the vertical direction). For example, the first semiconductor chip 200 may be spaced apart from the redistribution structure 100 in the third direction with the plurality of conductive pillars 220 and the molding layer ML in between.

The first semiconductor chip 200 may include an active surface 200_A and an opposite inactive surface. In some embodiments, the first semiconductor chip 200 may be positioned above the redistribution structure 100 such that the active surface 200_A of the first semiconductor chip 200 faces the redistribution structure 100. For example, the first semiconductor chip 200 may be mounted on the redistribution structure 100 in a face-down manner. For example, a top surface of the first semiconductor chip 200 may include an inactive surface of the first semiconductor chip 200 and a bottom surface of the first semiconductor chip 200 may include an active surface 200_A of the first semiconductor chip 200.

In some embodiments, the first semiconductor chip 200 may further include a plurality of first input/output terminals 210. The plurality of first input/output terminals 210 may be located on the active surface 200_A of the first semiconductor chip 200.

The plurality of conductive pillars 220 may be located on the bottom surface of the first semiconductor chip 200. For example, the plurality of conductive pillars 220 may be located below the plurality of first input/output terminals 210 of the first semiconductor chip 200. For example, the number of conductive pillars 220 may be the same as the number of first input/output terminals 210.

Each of the plurality of conductive pillars 220 may extend from the bottom surface of the first semiconductor chip 200 to the top surface of the redistribution structure 100. For example, one end of each of the plurality of conductive pillars 220 may be in contact with the plurality of first input/output terminals 210 of the first semiconductor chip 200 and the other end of each of the plurality of conductive pillars 220 may be in contact with the redistribution patterns 120 of the redistribution structure 100. The plurality of conductive pillars 220 may be configured to electrically connect the first semiconductor chip 200 to the redistribution structure 100. In some embodiments, the length of each of the plurality of conductive pillars 220 in the vertical direction (Z direction) may be about 20 μm to about 50 μm.

The second semiconductor chip 300 may be located on the first semiconductor chip 200. The second semiconductor chip 300 may be offset stacked on the first semiconductor chip 200 (i.e., the second semiconductor chip 300 is on the first semiconductor chip 200, but is offset relative to the first semiconductor chip, for example, along the X direction, as illustrated in FIG. 2). For example, the second semiconductor chip 300 may be offset stacked on the first semiconductor chip 200 such that the plurality of second input/output terminals 310 of the second semiconductor chip 300 are located outside or adjacent the first semiconductor chip 200 (i.e., the plurality of second input/output terminals 310 of the second semiconductor chip 300 are to the side of and spaced apart from the first semiconductor chip 200, as illustrated in FIG. 2).

In some embodiments, a first adhesive layer 240 may be located on the top surface of the first semiconductor chip 200. A portion of the first adhesive layer 240 may be located between the first semiconductor chip 200 and the second semiconductor chip 300. For example, a portion of a top surface of the first adhesive layer 240 may be in contact with the molding layer ML and the other portion of the top surface of the first adhesive layer 240 may be in contact with the second semiconductor chip 300. In some embodiments, the first adhesive layer 240 may include at least one of a non-conductive film (NCF) and a die attach film (DAF).

The second semiconductor chip 300 may include an active surface 300_A and an opposite inactive surface. In some embodiments, the second semiconductor chip 300 may be positioned above the redistribution structure 100 such that the active surface 300_A of the second semiconductor chip 300 faces the redistribution structure 100. For example, the second semiconductor chip 300 may be offset stacked on the first semiconductor chip 200 in a face-down manner.

In some embodiments, the second semiconductor chip 300 may further include the plurality of second input/output terminals 310. The plurality of second input/output terminals 310 may be located on the active surface 300_A of the second semiconductor chip 300.

The plurality of first conductive posts 320 may be located on a bottom surface of the second semiconductor chip 300. The plurality of first conductive posts 320 may extend from the bottom surface of the second semiconductor chip 300 to the top surface of the redistribution structure 100. The plurality of first conductive posts 320 are located inside the molding layer ML. The plurality of first conductive posts 320 may be configured to electrically connect the second semiconductor chip 300 to the redistribution structure 100.

In some embodiments, the length of each of the plurality of first conductive posts 320 in the vertical direction (Z direction) may be greater than the length of the plurality of conductive pillars 220 in the vertical direction (Z direction). In some embodiments, the length of each of the plurality of first conductive posts 320 in the vertical direction (Z direction) may be about 100 μm to about 300 μm.

The plurality of first conductive posts 320 may be spaced apart from the first semiconductor chip 200. For example, each of the plurality of first conductive posts 320 may extend from each of the plurality of second input/output terminals 310 of the second semiconductor chip 300 to the top surface of the redistribution structure 100. For example, as the plurality of second input/output terminals 310 of the second semiconductor chip 300 do not overlap with the first semiconductor chip 200, the plurality of first conductive posts 320 located below the plurality of second input/output terminals 310 may be spaced apart from the first semiconductor chip 200.

In some embodiments, the semiconductor package 1000 may further include a first seed layer 330. The first seed layer 330 may be located on a top surface of each of the plurality of first conductive posts 320. The first seed layer 330 may be located between each of the plurality of first conductive posts 320 and the second semiconductor chip 300. For example, the first seed layer 330 may be conformally formed on the top surface of each of the plurality of first conductive posts 320. For example, a side surface of the first seed layer 330 may be coplanar with a side surface of each of the plurality of first conductive posts 320.

The third semiconductor chip 400 may be located on the second semiconductor chip 300. The third semiconductor chip 400 may include an active surface 400_A and an opposite inactive surface. In some embodiments, the third semiconductor chip 400 may be disposed on the second semiconductor chip 300 such that the active surface 400_A of the third semiconductor chip 400 faces the redistribution structure 100. For example, the third semiconductor chip 400 may be stacked on the second semiconductor chip 300 in a face-down manner.

In some embodiments, a second adhesive layer 340 may be located on a top surface of the second semiconductor chip 300. The second adhesive layer 340 may be located between the second semiconductor chip 300 and the third semiconductor chip 400. In some embodiments, the second adhesive layer 340 may be at least one of an NCF and a DAF.

In some embodiments, a plurality of individual devices of various kinds may be located on the active surface 200_A of the first semiconductor chip 200, the active surface 300_A of the second semiconductor chip 300, and the active surface 400_A of the third semiconductor chip 400. The plurality of individual devices of each of the first semiconductor chip 200, the second semiconductor chip 300, and the third semiconductor chip 400 may be electrically connected to a wiring region of each of the first semiconductor chip 200, the second semiconductor chip 300, and the third semiconductor chip 400.

For example, the plurality of individual devices of each semiconductor chip may include various micro-electronic devices, e.g., a complementary metal-oxide semiconductor transistor (CMOS), a metal-oxide-semiconductor field effect transistor (MOSFET), a system large scale integration (LSI), an image sensor, such as a CMOS imaging sensor (CIS), a micro-electro-mechanical system (MEMS), an active device, and a passive device.

The area of the top surface of the third semiconductor chip 400 may be greater than the area of the top surface of the second semiconductor chip 300. For example, the area of the top surface of the third semiconductor chip 400 may be equal to the area of the top surface of the redistribution structure 100. For example, the top surface of the second semiconductor chip 300 may be completely covered by the third semiconductor chip 400. In some embodiments, the area of the top surface of the third semiconductor chip 400 may be 1.5 to 2 times the area of the top surface of the second semiconductor chip 300. In some embodiments, the area of the top surface of the second semiconductor chip 300 may be equal to the area of the top surface of the first semiconductor chip 200.

In some embodiments, the length of the third semiconductor chip 400 in a first direction (e.g. the first horizontal direction) may be greater than the length of the second semiconductor chip 300 in the first direction. The length of the third semiconductor chip 400 in a second direction (e.g. the first horizontal direction) may be greater than the length of the first semiconductor chip 200 in the second direction. For example, all side surfaces of the second semiconductor chip 300 may be located below a bottom surface of the third semiconductor chip 400.

For example, when each of the first semiconductor chip 200, the second semiconductor chip 300, and the third semiconductor chip 400 includes a memory semiconductor chip, such as dynamic random-access memory (DRAM), the number of individual devices included in the third semiconductor chip 400 may be twice the number of individual devices included in each of the first semiconductor chip 200 and the second semiconductor chip 300. For example, the third semiconductor chip 400 may have twice the capacity of the second semiconductor chip 300.

In some embodiments, the length of each of the first semiconductor chip 200, the second semiconductor chip 300, and the third semiconductor chip 400 in the vertical direction (Z direction) may be about 50 μm to about 150 μm. For example, as the capacity of the third semiconductor chip 400 increases, the required number of semiconductor chip stacks may decrease, thereby increasing the thickness of one semiconductor chip. Accordingly, the occurrence of cracks in semiconductor chips may be suppressed.

In some embodiments, the third semiconductor chip 400 may further include a plurality of third input/output terminals 410. The plurality of third input/output terminals 410 may be located on the active surface 400_A of the third semiconductor chip 400. The plurality of third input/output terminals 410 may not overlap with the second semiconductor chip 300 and the first semiconductor chip 200 in the vertical direction (Z direction). For example, the plurality of third input/output terminals 410 may be located outside or adjacent the second semiconductor chip 300 and the first semiconductor chip 200 (i.e., the plurality of third input/output terminals 410 of the third semiconductor chip 400 are to the side of and spaced apart from the second semiconductor chip 300 and the first semiconductor chip 200, as illustrated in FIG. 2).

In some embodiments, the number of third input/output terminals 410 of the third semiconductor chip 400 may be greater than the number of second input/output terminals 310 of the second semiconductor chip 300. For example, the number of third input/output terminals 410 may be twice the number of second input/output terminals 310.

In some embodiments, the plurality of third input/output terminals 410 may be divided into a first group G1 and a second group G2. For example, the number of third input/output terminals 410_1 included in the first group G1 may be equal to the number of second input/output terminals 310 of the second semiconductor chip 300. The number of third input/output terminals 410_2 included in the second group G2 may be equal to the number of second input/output terminals 310 of the second semiconductor chip 300.

In some embodiments, the plurality of third input/output terminals 410_1 included in the first group G1 may be arranged in a row in the second horizontal direction (Y direction) and the plurality of third input/output terminals 410_2 included in the second group G2 may be arranged in a row in the second horizontal direction (Y direction).

For example, the first group G1 and the second group G2 may be spaced apart from each other in the first horizontal direction (X direction). In some embodiments, the second semiconductor chip 300 may be arranged, on the bottom surface of the third semiconductor chip 400, between the plurality of third input/output terminals 410_1 included in the first group G1 and the plurality of third input/output terminals 410_2 included in the second group G2.

The plurality of second conductive posts 420 may be located on the bottom surface of the third semiconductor chip 400. The plurality of second conductive posts 420 may extend from the bottom surface of the third semiconductor chip 400 to the top surface of the redistribution structure 100. The plurality of second conductive posts 420 may be located inside the molding layer ML. The plurality of second conductive posts 420 may be configured to electrically connect the third semiconductor chip 400 to the redistribution structure 100.

Each of the plurality of second conductive posts 420 may extend from each of the plurality of third input/output terminals 410 of the third semiconductor chip 400 to the top surface of the redistribution structure 100. For example, as the plurality of third input/output terminals 410 of the third semiconductor chip 400 do not overlap with the first semiconductor chip 200 and the second semiconductor chip 300, the plurality of second conductive posts 420 located below the plurality of third input/output terminals 410 may be spaced apart from the first semiconductor chip 200 and the second semiconductor chip 300, as illustrated in FIG. 2.

For example, each of the plurality of conductive pillars 220, the plurality of first conductive posts 320, and the plurality of second conductive posts 420 may include a conductive material, e.g., Cu, Al, Ag, Sn, Au, Ni, Pb, Ti, or an alloy thereof.

In some embodiments, the number of second conductive posts 420 may be greater than the number of first conductive posts 320. The number of second conductive posts 420 may be equal to the number of third input/output terminals 410 and the number of first conductive posts 320 may be equal to the number of second input/output terminals 310. For example, the number of second conductive posts 420 may be twice the number of first conductive posts 320. For example, the number of first conductive posts 320 may be equal to the number of conductive pillars 220.

Some of the plurality of second conductive posts 420 may be in contact with the plurality of third input/output terminals 410_1 included in the first group G1 and the others of the plurality the second conductive posts 420 may be in contact with the plurality of the third input/output terminals 410_2 included in the second group G2. The plurality of second conductive posts 420 in contact with the plurality of third input/output terminals 410_1 included in the first group G1 and the plurality of second conductive posts 420 in contact with the plurality of third input/output terminals 410_2 included in the second group G2 may be spaced apart from each other in the horizontal direction.

In some embodiments, the first semiconductor chip 200 and the second semiconductor chip 300 may be located between the second conductive post 420 located below the third input/output terminal 410_1 included in the first group G1 among the plurality of second conductive posts 410 and the second conductive post 420 located below the third input/output terminal 410_2 included in the second group G2 among the plurality of first conductive posts 420.

In some embodiments, the semiconductor package 1000 may further include a second seed layer 430. The second seed layer 430 may be located on a top surface of each of the plurality of second conductive posts 420. The second seed layer 430 may be located between each of the plurality of second conductive posts 420 and the third semiconductor chip 400. For example, the second seed layer 430 may be conformally formed on the top surface of each of the plurality of second conductive posts 420. For example, a side surface of the second seed layer 430 may be coplanar with a side surface of each of the plurality of second conductive posts 420. In some embodiments, a top surface of the second seed layer 430 may be coplanar with a top surface of the molding layer ML.

The molding layer ML may be located on the redistribution structure 100. The molding layer ML may be located between the redistribution structure 100 and the third semiconductor chip 400. The molding layer ML may be located between the top surface of the redistribution structure 100 and the bottom surface of the third semiconductor chip 400. The molding layer ML may surround the plurality of conductive pillars 220, the plurality of first conductive posts 320, the plurality of second conductive posts 420, the first semiconductor chip 200, and the second semiconductor chip 300.

In some embodiments, the side surface of the molding layer ML, the side surface of the redistribution structure 100, and the side surface of the third semiconductor chip 400 may be coplanar. The top surface of the molding layer ML may be spaced apart from the top surface of the third semiconductor chip 400 in the vertical direction (Z direction). The side surface and the top surface of the third semiconductor chip 400 may be exposed to the outside. The length of the molding layer ML in the third direction (e.g. the vertical direction) may be equal to the length of each of the plurality of second conductive posts 420 in the third direction.

In some embodiments, the bottom surface of each of the plurality of conductive pillars 220, the bottom surface of each of the plurality of first conductive posts 320, the bottom surface of each of the plurality of second conductive posts 420, and the bottom surface of the molding layer ML may be coplanar. For example, the plurality of conductive pillars 220, the plurality of first conductive posts 320, and the plurality of second conductive posts 420 may contact the redistribution vias RV of the redistribution patterns 120 of the redistribution structure 100.

In some embodiments, the molding layer ML may include an epoxy resin or a polyimide resin. The molding layer ML may include, for example, an epoxy molding compound (EMC).

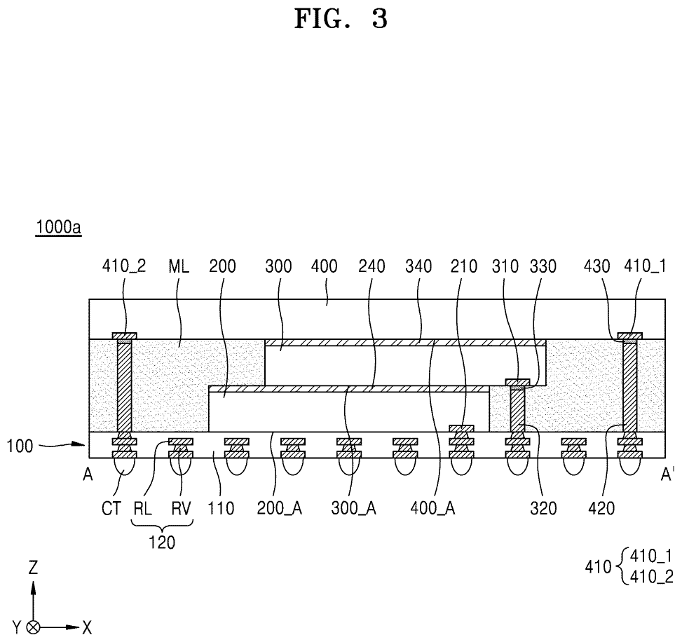

FIG. 3 is a schematic cross-sectional view of a semiconductor package 1000a according to an embodiment.

Most of the components that form the semiconductor package 1000a described below and the materials that make up the components are substantially the same as or similar to those previously described with reference to FIG. 2. Therefore, for convenience of description, the differences between the semiconductor package 1000a of FIG. 3 and the semiconductor package 1000 of FIG. 2 described above may be mainly described.

Referring to FIG. 3, the semiconductor package 1000a may include a redistribution structure 100, a first semiconductor chip 200, a second semiconductor chip 300, a plurality of first conductive posts 320, a third semiconductor chip 400, a plurality of second conductive posts 420, and a molding layer ML. Unlike the semiconductor package 1000 of FIG. 2, the semiconductor package 1000a of FIG. 3 may not include the plurality of conductive pillars 220 (see FIG. 2).

A bottom surface of the first semiconductor chip 200 of the semiconductor package 1000a may be in contact with a top surface of the redistribution structure 100. For example, first input/output terminals 210 of the first semiconductor chip 200 may be in contact with redistribution patterns 120 of the redistribution structure 100. The bottom surface of the first semiconductor chip 200 and the bottom surface of the molding layer ML may be coplanar.

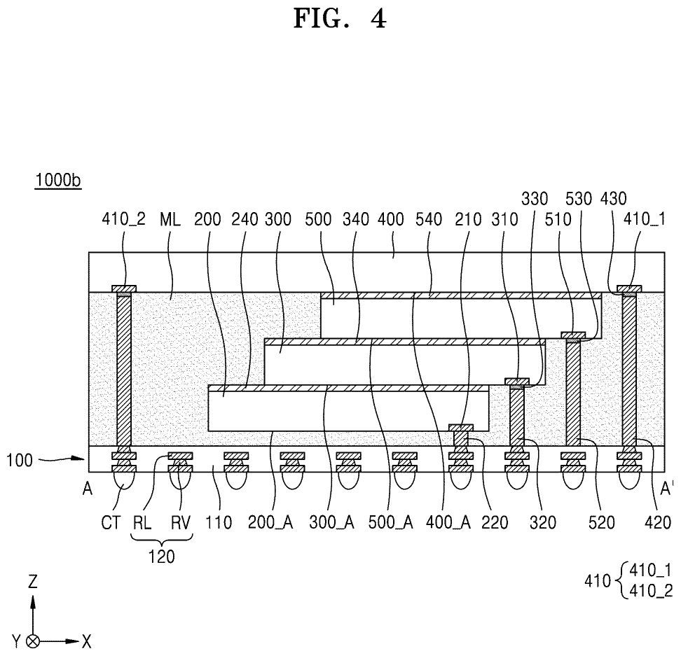

FIG. 4 is a schematic plan view of a semiconductor package 1000b according to an embodiment.

Most of the components that form the semiconductor package 1000b described below and the materials that make up the components are substantially the same as or similar to those previously described with reference to FIG. 2. Therefore, for convenience of description, the differences between the semiconductor package 1000b of FIG. 4 and the semiconductor package 1000 of FIG. 2 described above may be mainly described.

Referring to FIG. 4, the semiconductor package 1000b may include a redistribution structure 100, a first semiconductor chip 200, a plurality of conductive pillars 220, a second semiconductor chip 300, a plurality of first conductive posts 320, a third semiconductor chip 400, a plurality of second conductive posts 420, and a molding layer ML. The semiconductor package 1000b may further include a fourth semiconductor chip 500 and a plurality of third conductive posts 520.

The fourth semiconductor chip 500 may be located on the second semiconductor chip 300. The fourth semiconductor chip 500 may be offset stacked on the second semiconductor chip 300 (i.e., the fourth semiconductor chip 500 is on the second semiconductor chip 300, but is offset relative to the second semiconductor chip 300, for example, along the X direction as illustrated in FIG. 4). For example, a portion of the fourth semiconductor chip 500 may not overlap with the first semiconductor chip 200 and the second semiconductor chip 300 in the vertical direction (Z direction).

The fourth semiconductor chip 500 may include an active surface 500_A and an opposite inactive surface. In some embodiments, the fourth semiconductor chip 500 may be disposed on the second semiconductor chip 300 such that the active surface 500_A of the fourth semiconductor chip 500 faces the redistribution structure 100. For example, the fourth semiconductor chip 500 may be offset stacked on the second semiconductor chip 300 in a face-down manner.

In some embodiments, the fourth semiconductor chip 500 may further include a plurality of fourth input/output terminals 510. The plurality of fourth input/output terminals 510 may be located on the active surface 500_A of the fourth semiconductor chip 500. The plurality of fourth input/output terminals 510 may not overlap with the first semiconductor chip 200 and the second semiconductor chip 300 in the vertical direction (Z direction). For example, the plurality of fourth input/output terminals 510 may be located outside the first semiconductor chip 200 and the second semiconductor chip 300 (i.e., the plurality of fourth input/output terminals 510 of the fourth semiconductor chip 500 are to the side of and spaced apart from the first semiconductor chip 200 and the second semiconductor chip 300, as illustrated in FIG. 4).

The plurality of third conductive posts 520 may be located on the bottom surface of the fourth semiconductor chip 500. The plurality of third conductive posts 520 may extend from the bottom surface of the fourth semiconductor chip 500 to the top surface of the redistribution structure 100. The plurality of third conductive posts 520 may be located inside the molding layer ML. The plurality of third conductive posts 520 may be configured to electrically connect the fourth semiconductor chip 500 to the redistribution structure 100.

Each of the plurality of third conductive posts 520 may extend from each of the plurality of fourth input/output terminals 510 of the fourth semiconductor chip 500 to the top surface of the redistribution structure 100. For example, as the plurality of fourth input/output terminals 510 of the fourth semiconductor chip 500 do not overlap with the first semiconductor chip 200 and the second semiconductor chip 300, the plurality of third conductive posts 520 located below the plurality of fourth input/output terminals 510 may be spaced apart from the first semiconductor chip 200 and the second semiconductor chip 300.

For example, each of the plurality of third conductive posts 520 may include a conductive material, e.g., Cu, Al, Ag, Sn, Au, Ni, Pb, Ti, or an alloy thereof.

In some embodiments, the semiconductor package 1000b may further include a fourth seed layer 530. The fourth seed layer 530 may be located on a top surface of each of the plurality of third conductive posts 520. The fourth seed layer 530 may be located between each of the plurality of third conductive posts 520 and the fourth semiconductor chip 500. For example, the fourth seed layer 530 may be conformally formed on the top surface of each of the plurality of third conductive posts 520. For example, a side surface of the fourth seed layer 530 may be coplanar with a side surface of each of the plurality of third conductive posts 520.

The third semiconductor chip 400 may be located on the fourth semiconductor chip 500. For example, the third semiconductor chip 400 may be located on the molding layer ML and the fourth semiconductor chip 500. In some embodiments, a third adhesive layer 540 may be located between the fourth semiconductor chip 500 and the third semiconductor chip 400. Through the third adhesive layer 540, the fourth semiconductor chip 500 may be fixed to the third semiconductor chip 400.

The plurality of second conductive posts 420 may extend from the bottom surface of the third semiconductor chip 400 to the top surface of the redistribution structure 100. The plurality of second conductive posts 420 may be spaced apart from the first semiconductor chip 200, the second semiconductor chip 300, and the fourth semiconductor chip 500. For example, the plurality of second conductive posts 420 may be located inside the molding layer ML.

FIG. 4 shows three semiconductor chips stacked under the third semiconductor chip 400, but the number of semiconductor chips stacked under the fourth semiconductor chip 400 is not limited thereto.

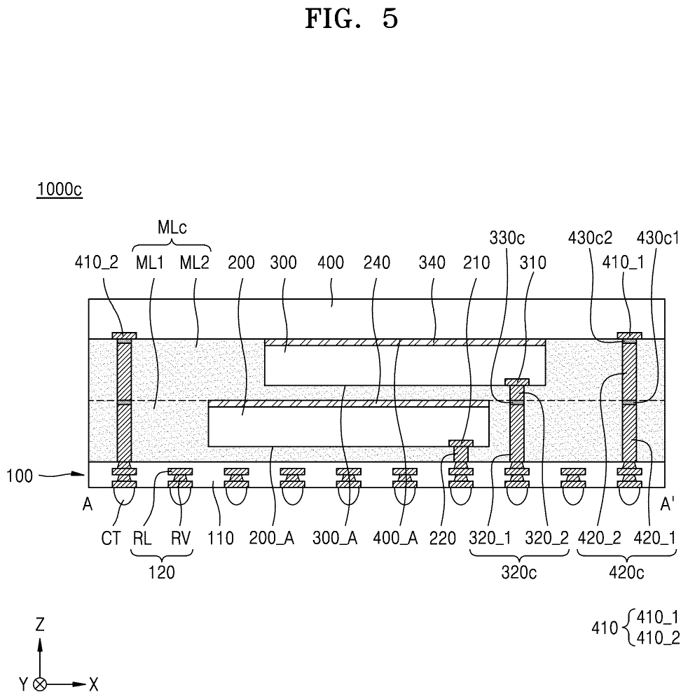

FIG. 5 is a schematic plan view of a semiconductor package 1000c according to an embodiment.

Most of the components that form the semiconductor package 1000c described below and the materials that make up the components are substantially the same as or similar to those previously described with reference to FIG. 2. Therefore, for convenience of description, the differences between the semiconductor package 1000c of FIG. 5 and the semiconductor package 1000 of FIG. 2 described above may be mainly described.

Referring to FIG. 5, the semiconductor package 1000c may include a redistribution structure 100, a first semiconductor chip 200, a plurality of conductive pillars 220, a second semiconductor chip 300, a plurality of first conductive posts 320c, a third semiconductor chip 400, a plurality of second conductive posts 420c, and a molding layer MLc.

The molding layer MLc may include a first molding layer ML1 and a second molding layer ML2. The second molding layer ML2 may be located on the first molding layer ML1. For example, the first molding layer ML1 may be referred to as a lower molding layer and the second molding layer ML2 may be referred to as an upper molding layer.

As shown in FIG. 5, the first molding layer ML1 and the second molding layer ML2 may be integrally formed without a boundary between the first molding layer ML1 and the second molding layer ML2. However, the inventive concept is not limited thereto. Because of the difference between the curing time of the first molding layer ML1 and the curing time of the second molding layer ML2, there may be an interface between the first molding layer ML1 and the second molding layer ML2.

The first molding layer ML1 may be located on the redistribution structure 100. The first molding layer ML1 may surround the first semiconductor chip 200 and the plurality of conductive pillars 220. The second molding layer ML2 may be located between a top surface of the first molding layer ML1 and a bottom surface of the third semiconductor chip 400. For example, the second molding layer ML2 may be in contact only with the bottom surface of the third semiconductor chip 400 among all surfaces of the third semiconductor chip 400. The second molding layer ML2 may surround the second semiconductor chip 300, a portion of each of the plurality of first conductive posts 320c, and a portion of each of the plurality of second conductive posts 420c.

The second semiconductor chip 300 may be located above the first molding layer ML1. For example, the second semiconductor chip 300 may be spaced apart from the first molding layer ML1 in the vertical direction (Z direction). The second semiconductor chip 300 may be spaced apart from the first semiconductor chip 200 in the vertical direction (Z direction). For example, a first adhesive layer 240 may be located between the first semiconductor chip 200 and the second molding layer ML2.

The second molding layer ML2 may be located between the first semiconductor chip 200 and the second semiconductor chip 300. For example, the bottom surface of the second semiconductor chip 300 may be in contact with the second molding layer ML2. For example, the second semiconductor chip 300 may be embedded inside the second molding layer ML2.

In some embodiments, the second semiconductor chip 300 may be located above the first molding layer ML1 and may be offset relative to the first semiconductor chip 200, as illustrated in FIG. 5. For example, the second semiconductor chip 300 may be offset relative to the first semiconductor chip 200 such that the plurality of second input/output terminals 310 of the second semiconductor chip 300 are not located on top of the first semiconductor chip 200 (e.g., the plurality of second input/output terminals 310 are located adjacent to the first semiconductor chip 200, as illustrated in FIG. 5).

In some embodiments, each of the plurality of first conductive posts 320c may be divided into a first upper conductive post 320_2 and a first lower conductive post 320_1. For example, the first upper conductive post 320_2 may be referred to as a conductive pillar of the second semiconductor chip 300. Each of the plurality of second conductive posts 420c may be divided into a second upper conductive post 420_2 and a second lower conductive post 420_1.

The first upper conductive post 320_2 may include a portion of the first conductive post 320c inside the second molding layer ML2 and the first lower conductive post 320_1 may include a portion of the first conductive post 320c inside the first molding layer ML1. The second upper conductive post 420_2 may include a portion of the second conductive post 420c inside the second molding layer ML2 and the second lower conductive post 420_1 may include a portion of the second conductive post 420c inside the first molding layer ML1.

In some embodiments, the length of the first lower conductive post 320_1 in the vertical direction (Z direction) may be equal to the length of the second lower conductive post 420_1 in the vertical direction (Z directions). For example, the length of the first lower conductive post 320_1 in the vertical direction (Z direction) and the length of the second lower conductive post 420_1 in the vertical direction (Z direction) may each be equal to the length of the first molding layer ML1 in the vertical direction (Z direction).

The semiconductor package 1000c may further include a first seed layer 330c, a second seed layer 430c2, and a third seed layer 430c1. The first seed layer 330c may be located inside each of the plurality of first conductive posts 320c. The second seed layer 430c2 may be located on a top surface of each of the plurality of second conductive posts 420c. The third seed layer 430cl may be located inside each of the plurality of second conductive posts 420c. For example, a side surface of the first seed layer 330c may be coplanar with a side surface of each of the plurality of first conductive posts 320c; and a side surface of each of the second seed layer 430c2 and the third seed layer 430cl may be coplanar with a side surface of each of the plurality of second conductive posts 420c.

In some embodiments, the first seed layer 330c may be positioned between the first upper conductive post 320_2 and the first lower conductive post 320_1. The third seed layer 430cl may be positioned between the second upper conductive post 420_2 and the second lower conductive post 420_1. The second seed layer 430c2 may be located between a top surface of the second upper conductive post 420_2 and a bottom surface of each of the plurality of third input/output terminals 410 of the third semiconductor chip 400.

In some embodiments, a top surface of the first seed layer 330c, a top surface the third seed layer 430cl, and a top surface of first molding layer ML1 may be coplanar. For example, the top surface of the first adhesive layer 240 may also be coplanar with the top surface of the first seed layer 330c, the top surface of the third seed layer 430cl, and the top surface of the first molding layer ML1.

In some embodiments, the distance between the top surface of the first seed layer 330c and the top surface of the redistribution structure 100 may be the same as the distance between the top surface of the third seed layer 430cl and the top surface of the redistribution structure 100.

A side surface of the first molding layer ML1 and a side surface of the second molding layer ML2 may be coplanar. The side surface of the first molding layer ML1, the side surface of the second molding layer ML2, the side surface of the redistribution structure 100, and the side surface of the third semiconductor chip 400 may be coplanar.

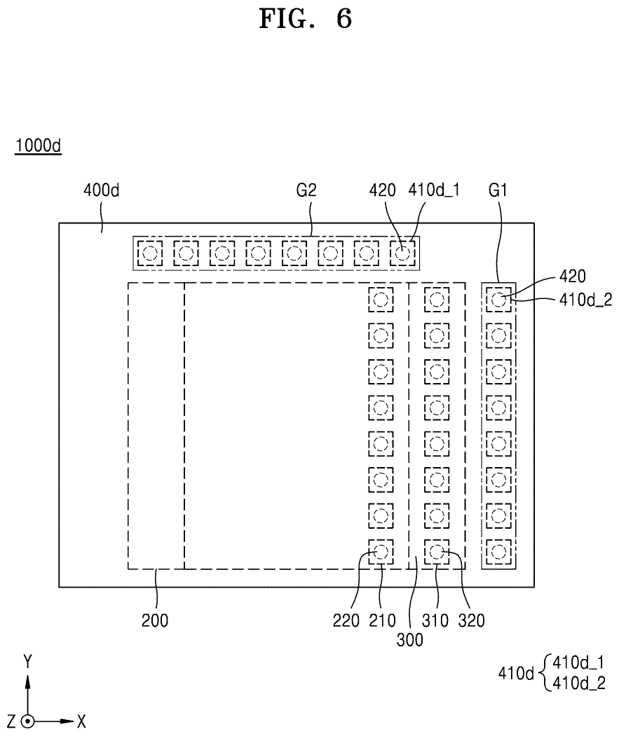

FIG. 6 is a schematic plan view of a semiconductor package 1000d according to an embodiment.

Most of the components that form the semiconductor package 1000d described below and the materials that make up the components are substantially the same as or similar to those previously described with reference to FIG. 1. Therefore, for convenience of description, the differences between the semiconductor package 1000d of FIG. 6 and the semiconductor package 1000 of FIG. 1 described above may be mainly described.

Referring to FIG. 6, the semiconductor package 1000d may include a redistribution structure 100 (see FIG. 2), a first semiconductor chip 200, a plurality of conductive pillars 220, a second semiconductor chip 300, a plurality of first conductive posts 320, a third semiconductor chip 400d, a plurality of second conductive posts 420, and a molding layer ML.

The first semiconductor chip 200 may include a plurality of first input/output terminals 210. The second semiconductor chip 300 may include a plurality of second input/output terminals 310. The third semiconductor chip 400d may include a plurality of third input/output terminals 410d. For example, the plurality of second input/output terminals 310 of the second semiconductor chip 300 may not overlap with the first semiconductor chip 200 in the vertical direction (Z direction). For example, the plurality of second input/output terminals 310 of the second semiconductor chip 300 may be located outside of (i.e., adjacent to) the first semiconductor chip 200. The plurality of third input/output terminals 410d of the third semiconductor chip 400d may not overlap with the second semiconductor chip 300 and the first semiconductor chip 200 in the vertical direction (Z direction).

The number of third input/output terminals 410d may be greater than the number of first input/output terminals 210 and the number of second input/output terminals 310. In some embodiments, the number of first input/output terminals 210 may be equal to the number of second input/output terminals 310 and the number of third input/output terminals 410d may be twice the number of second input/output terminals 310.

In some embodiments, the plurality of third input/output terminals 410d may be divided into a first group G1 and a second group G2. For example, the number of third input/output terminals 410d_1 included in the first group G1 may be equal to the number of second input/output terminals 310 and the number of third input/output terminal 410d_2 included in the second group G2 may be equal to the number of second input/output terminals 310.

In some embodiments, the plurality of third input/output terminals 410d_1 included in the first group G1 may be arranged in a row in the second horizontal direction (Y direction) and the plurality of third input/output terminals 410d_2 included in the second group G2 may be arranged in a row in the first horizontal direction (X direction). For example, the first group G1 may be arranged in a row along a first edge of the bottom surface of the third semiconductor chip 400d and the second group G2 may be arranged in a row along a second edge that is adjacent to the first edge of the bottom surface of the third semiconductor chip 400d.

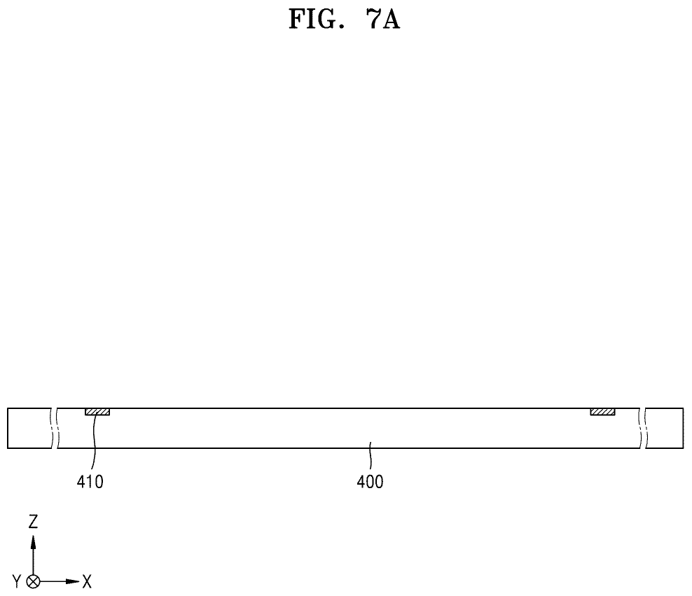

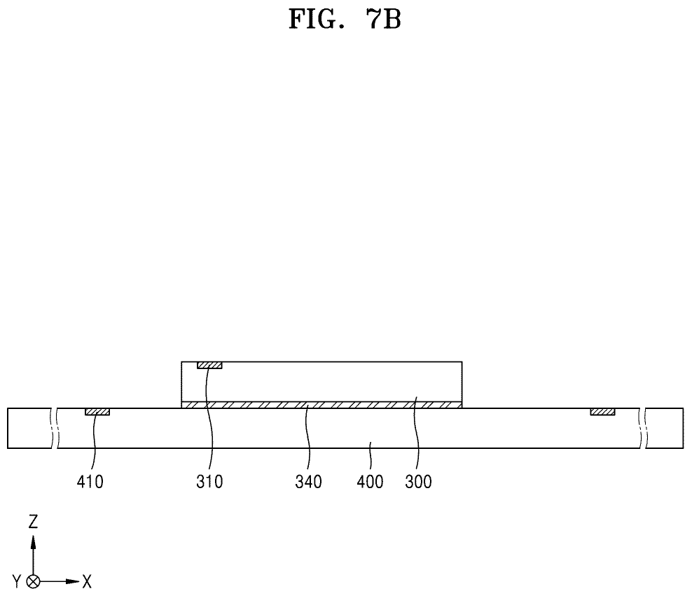

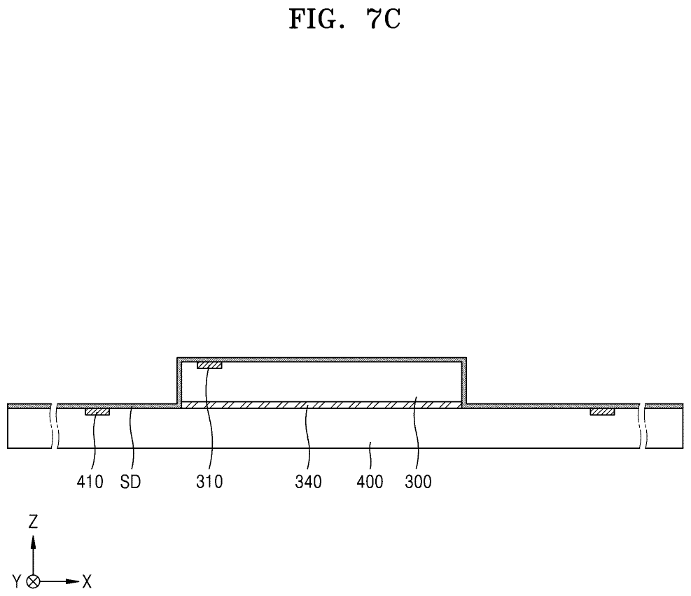

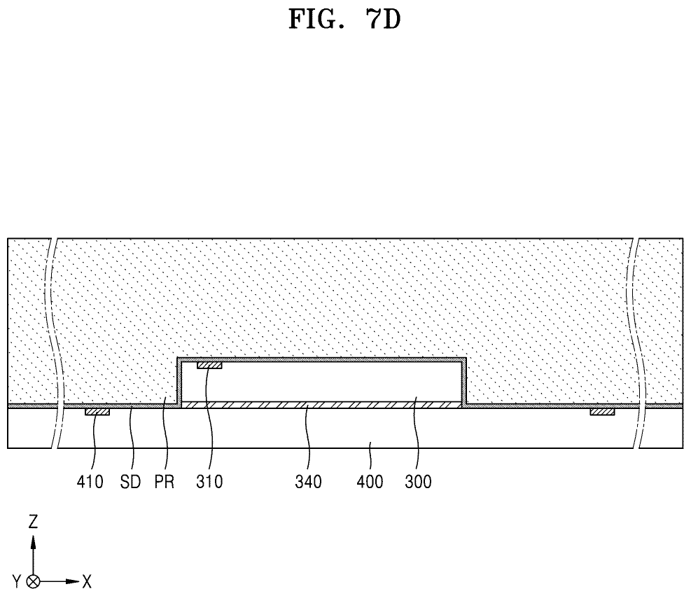

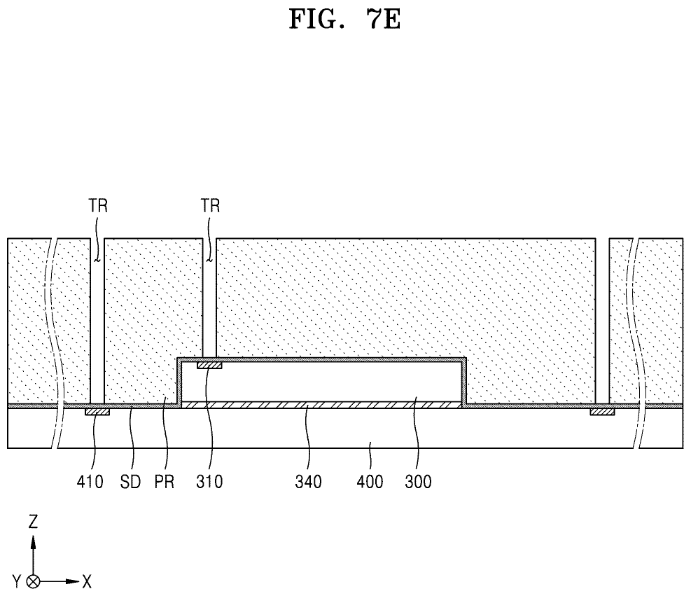

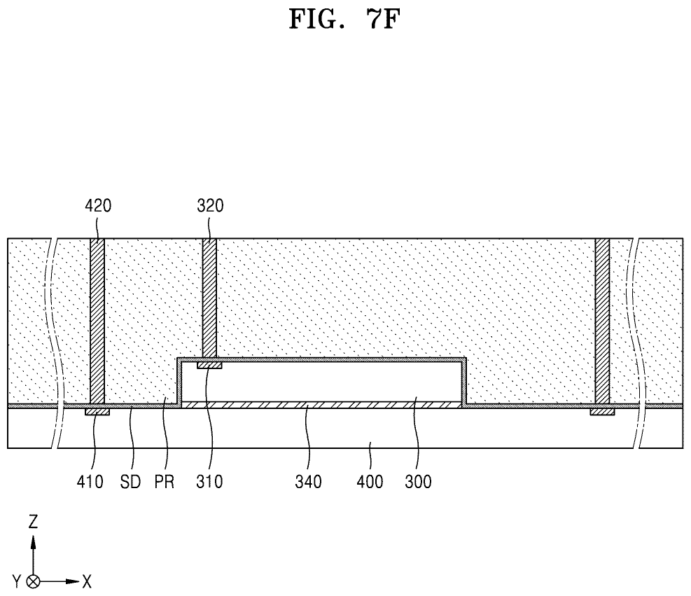

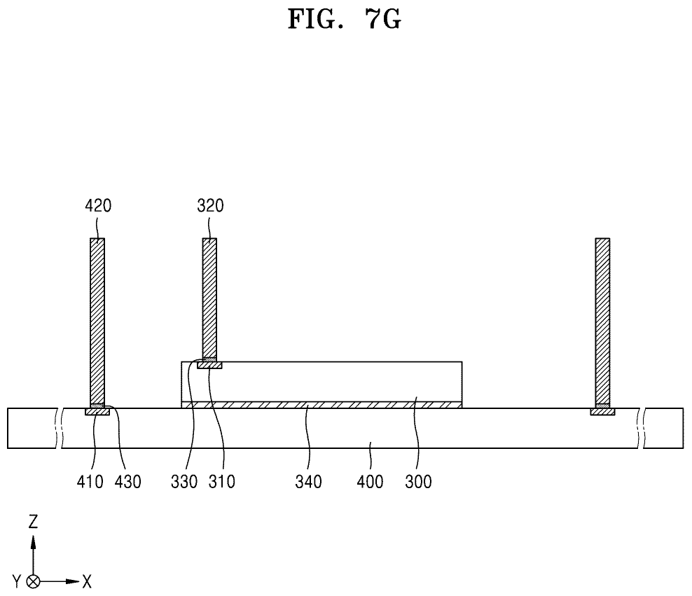

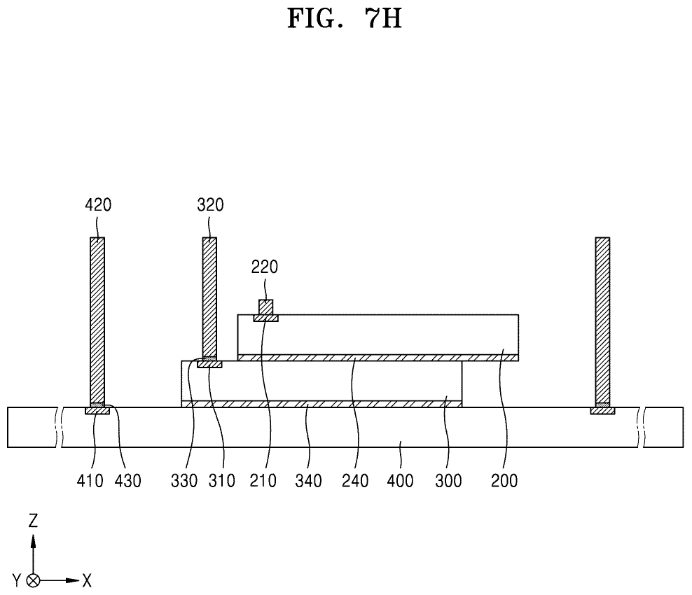

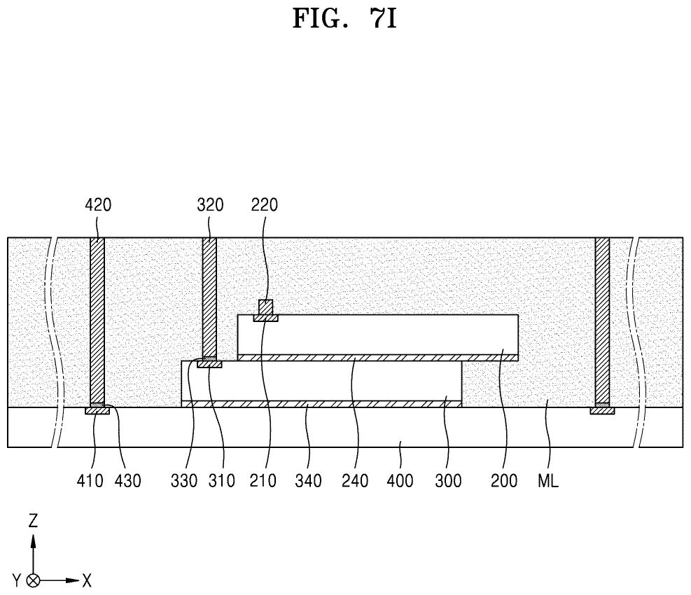

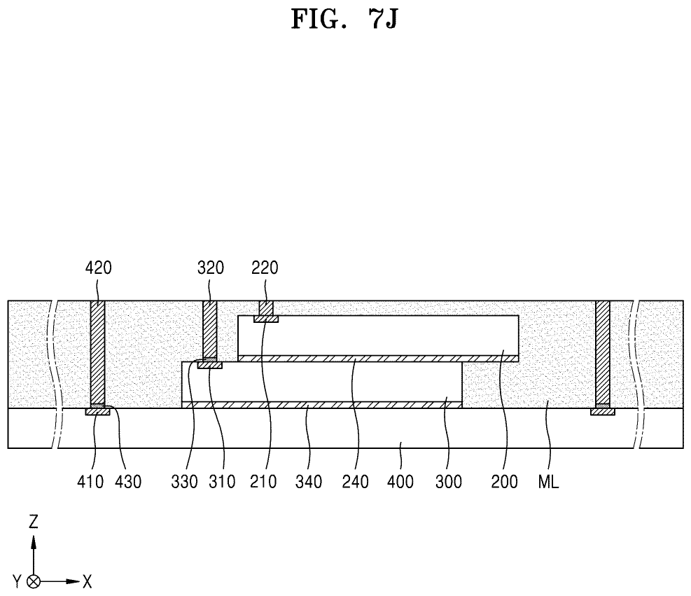

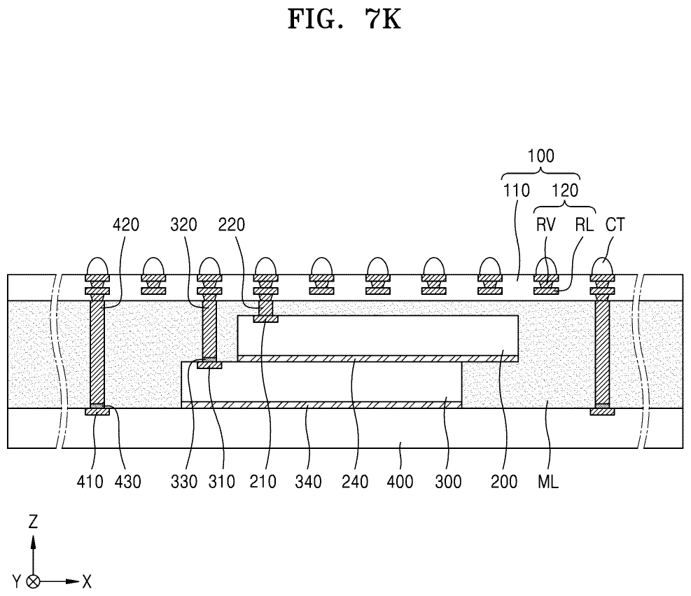

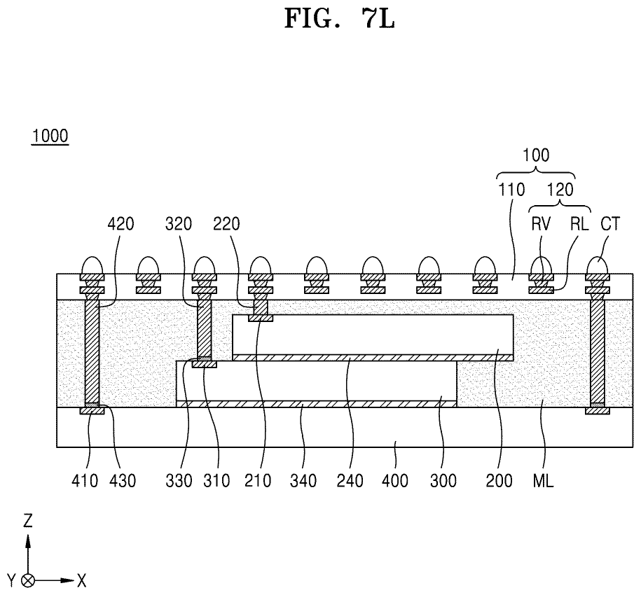

FIGS. 7A to 7L are diagrams illustrating a method of manufacturing a semiconductor package 1000 according to a process sequence, according to an embodiment.

Referring to FIGS. 7A to 7L, a first semiconductor chip 200 and a second semiconductor chip 300 may be stacked on a third semiconductor chip 400 without a separate carrier substrate to fabricate the semiconductor package 1000.

Referring to FIGS. 7A and 7B, the second semiconductor chip 300 may be mounted on the third semiconductor chip 400, which is in a wafer state before being diced into individual semiconductor chips. For example, the third semiconductor chip 400 may be arranged such that a plurality of third input/output terminals 410 located on an active surface of the third semiconductor chip 400 face upward in the vertical direction (Z direction). The second semiconductor chip 300 may be mounted on the third semiconductor chip 400 so as not to overlap with the plurality of third input/output terminals 410 of the third semiconductor chip 400 in the vertical direction (Z direction).

The second semiconductor chip 300 may be mounted on the third semiconductor chip 400 such that a second input/output terminal 310 located on the active surface of the second semiconductor chip 300 faces upward in the vertical direction (Z direction). For example, the second semiconductor chip 300 may be fixed to the third semiconductor chip 400 through a second adhesive layer 340 located on the bottom surface of the second semiconductor chip 300.

Referring to FIGS. 7C to 7G, a plurality of first conductive posts 320 located on the second semiconductor chip 300 and a plurality of second conductive posts 420 located on the third semiconductor chip 400 may be fabricated. For example, the plurality of first conductive posts 320 and the plurality of second conductive posts 420 may be formed through an electrolytic plating process.

Referring to FIG. 7C, a seed layer SD may be formed on the top surface of the resultant of FIG. 7B. The seed layer SD may be conformally formed on the exposed portion of the top surface of the third semiconductor chip 400 and the top surface and side surfaces of the second semiconductor chip 300.

Referring to FIGS. 7D and 7E, after forming a photoresist PR on top of the resultant of FIG. 7C, a plurality of trenches TR extending from the top surface to the bottom surface of the photoresists PR may be formed through a photo process. The plurality of trenches TR may be located on top of the plurality of third input/output terminals 410 and the plurality of second input/output terminals 310. Accordingly, portions of the seed layer SD located on the top surfaces of the plurality of third input/output terminals 410 and portions of the seed layer SD located on the top surfaces of the plurality of second input/output terminals 310 may be exposed to the outside through the plurality of trenches TR.

Referring to FIG. 7E, through an electrolytic plating process, the plurality of trenches TR may be filled with a conductive material to form the plurality of first conductive posts 320 and the plurality of second conductive posts 420. For example, in the electrolytic plating process, the seed layer SD may be used as a starting point to fill the plurality of trenches TR with the conductive material. The plurality of first conductive posts 320 may be formed in trenches TR, among the plurality of trenches TR, located above the plurality of second input/output terminals 310 and the plurality of second conductive posts 420 may be formed in trenches TR, among the plurality of trenches TR, located above the plurality of third input/output terminals 410.

Referring to FIG. 7G, the photoresist PR and a portion of the seed layer SD may be removed. When the photoresist PR is removed, a portion of the seed layer SD located on the bottom surface of the photoresist PR may be exposed to the outside. Thereafter, the portion of the seed layer SD exposed to the outside may be removed, thereby leaving portions of the seed layer SD located on the bottom surfaces of the plurality of first conductive posts 320 and portions of the seed layer SD located on the bottom surfaces of the plurality of second conductive posts 420.

For example, a first seed layer 330 may include a seed layer SD located on a bottom surface of each of the plurality of first conductive posts 320 and a second seed layer 430 may include a seed layer SD located on a bottom surface of each of the plurality of second conductive posts 420.

Referring to FIG. 7H to FIG. 7J, after mounting the first semiconductor chip 200 on the second semiconductor chip 300, a molding layer ML located on the third semiconductor chip 400 may be formed. The first semiconductor chip 200 may be offset stacked on the second semiconductor chip 300. For example, the first semiconductor chip 200 may be mounted on the second semiconductor chip 300 such that a plurality of first input/output terminals 210 located on the active surface of the first semiconductor chip 200 face upward in the vertical direction (Z direction).

The first semiconductor chip 200 may be offset stacked on the second semiconductor chip 300 so as to be spaced apart from the plurality of first conductive posts 320 and the plurality of second conductive posts 420. For example, the first semiconductor chip 200 may be offset stacked on the second semiconductor chip 300 through a first adhesive layer 240 located on the bottom surface of the first semiconductor chip 300.

For example, a plurality of conductive pillars 220 may be located on the plurality of first input/output terminals 210 of the first semiconductor chip 200. For example, the plurality of conductive pillars 220 may be attached to the first semiconductor chip 200 in the process of manufacturing the first semiconductor chip 200. For example, the first semiconductor chip 200 may be offset stacked on the second semiconductor chip 300 with the plurality of conductive pillars 220 attached to the second semiconductor chip 300.

In some embodiments, the length of the plurality of conductive pillars 220 in the vertical direction (Z direction) may be about 5 μm to about 40 μm. In some embodiments, there may be no separate seed layer between the plurality of conductive pillars 220 and the plurality of first input/output terminals 210.

Thereafter, the molding layer ML located on the third semiconductor chip 400 may cover the second semiconductor chip 300, the first semiconductor chip 200, the plurality of second conductive posts 420, the plurality of first conductive posts 320, and the plurality of conductive pillars 220. A portion of the molding layer ML may then be removed through a polishing process such that top surfaces of the plurality of conductive pillars 220, top surfaces of the plurality of first conductive posts 320, and top surfaces of the plurality of second conductive posts 420 are exposed to the outside. Accordingly, the top surfaces of the plurality of conductive pillars 220, the top surfaces the plurality of first conductive posts 320, the top surfaces of the plurality of second conductive posts 420, and the top surface of the molding layer ML may be coplanar.

Referring to FIG. 7K, the redistribution structure 100 may be formed on the molding layer ML. The redistribution patterns 120 of the redistribution structure 100 may be in contact with the plurality of first conductive posts 320, the plurality of second conductive posts 420, and the plurality of conductive pillars 220. Accordingly, the first semiconductor chip 200, the second semiconductor chip 300, and the third semiconductor chip 400 may be electrically connected to the redistribution structure 100. For example, external connection terminals CT may be attached to the top surface of the redistribution structure 100. In some embodiments, the width of the redistribution via RV of the redistribution pattern 120 of the redistribution structure 100 may narrow downward in the vertical direction (Z direction).

Referring to FIG. 7L, the resultant of FIG. 7K may be diced into multiple pieces. The resultant of FIG. 7K may be divided through processes, such as blade dicing, laser dicing, and stealth dicing. Accordingly, the side surface of the third semiconductor chip 400, the side surface of the molding layer ML, and the side surface of the redistribution structure 100 may be coplanar.

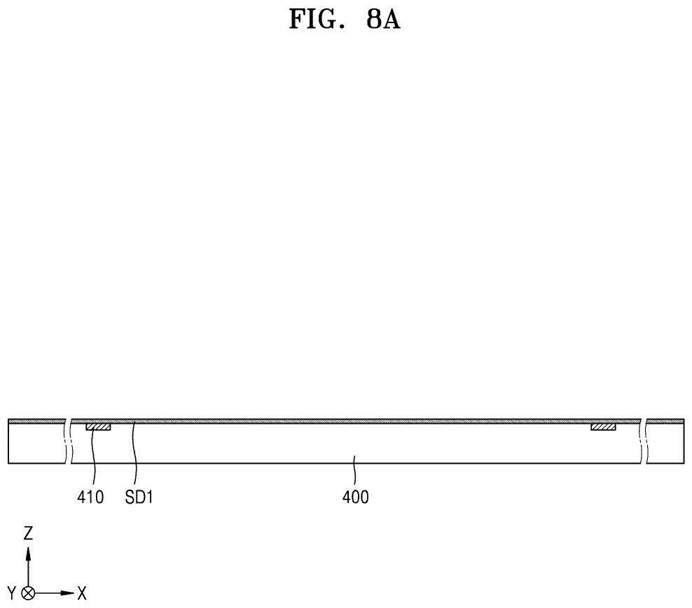

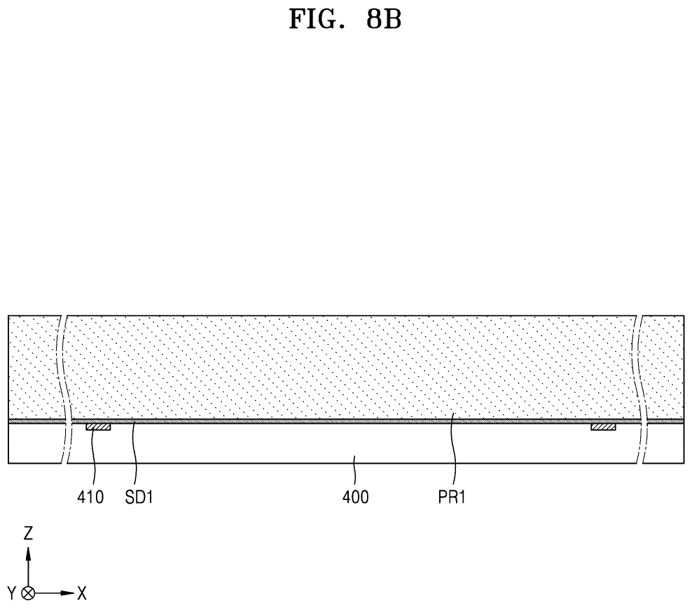

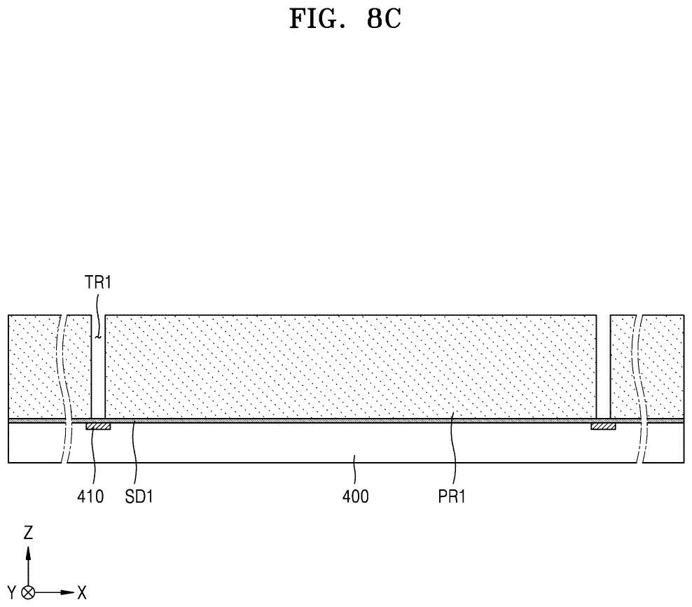

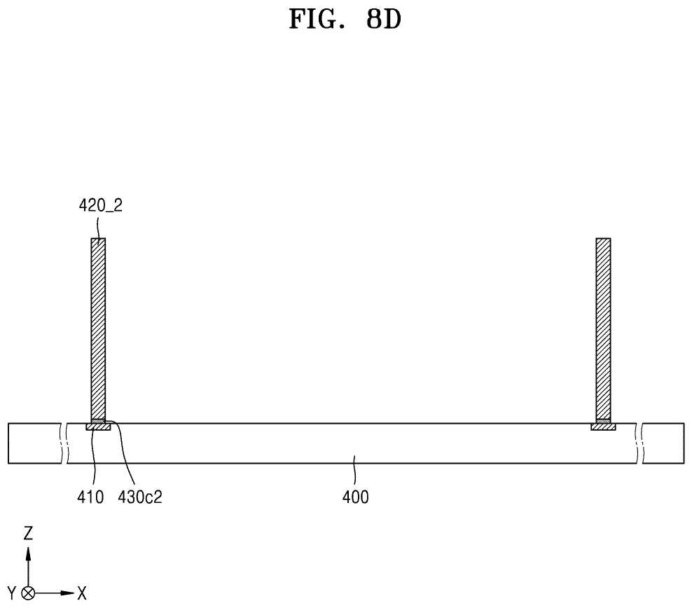

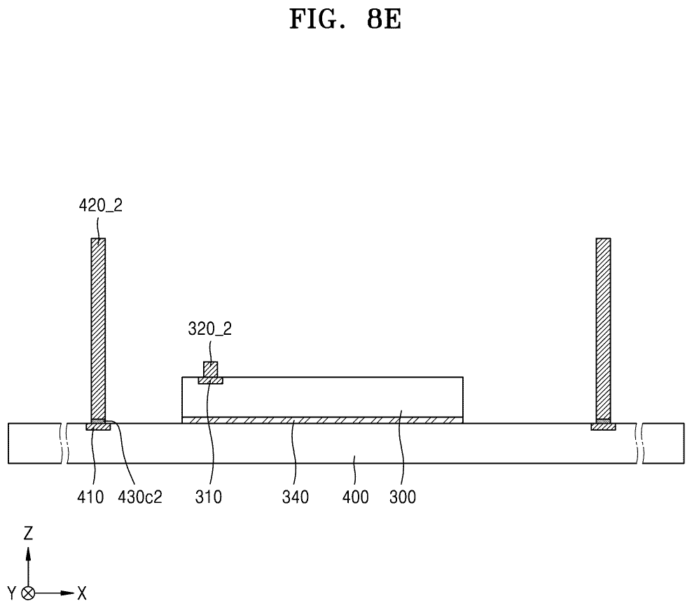

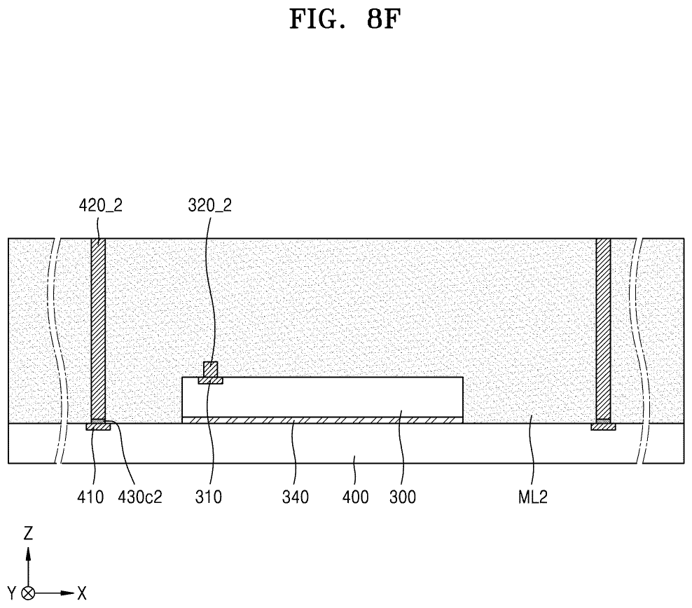

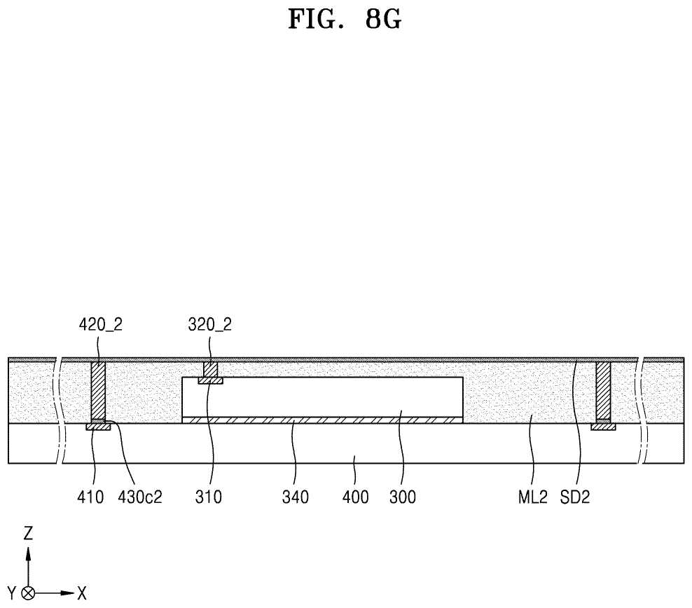

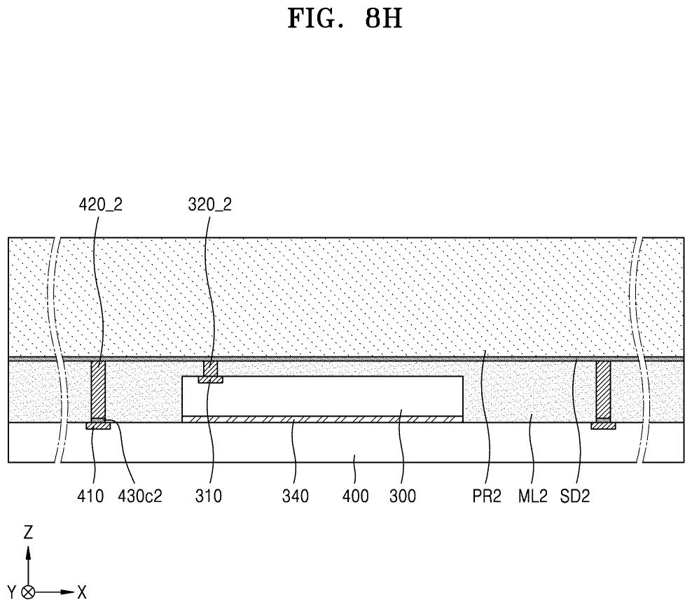

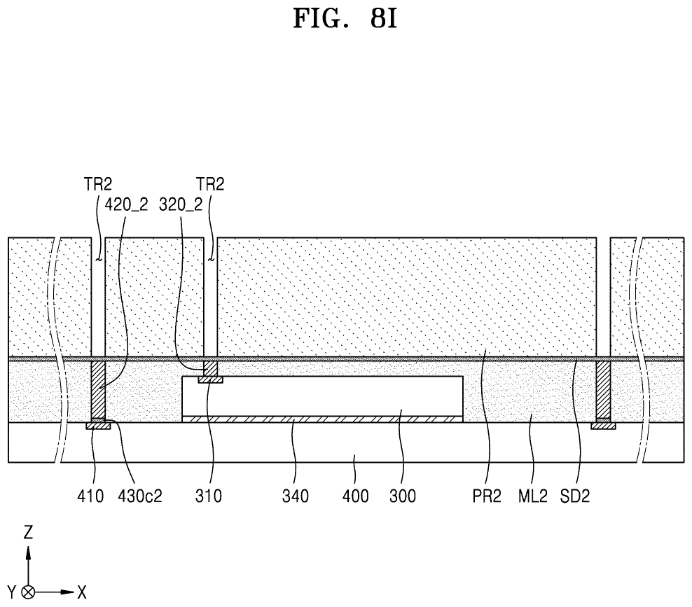

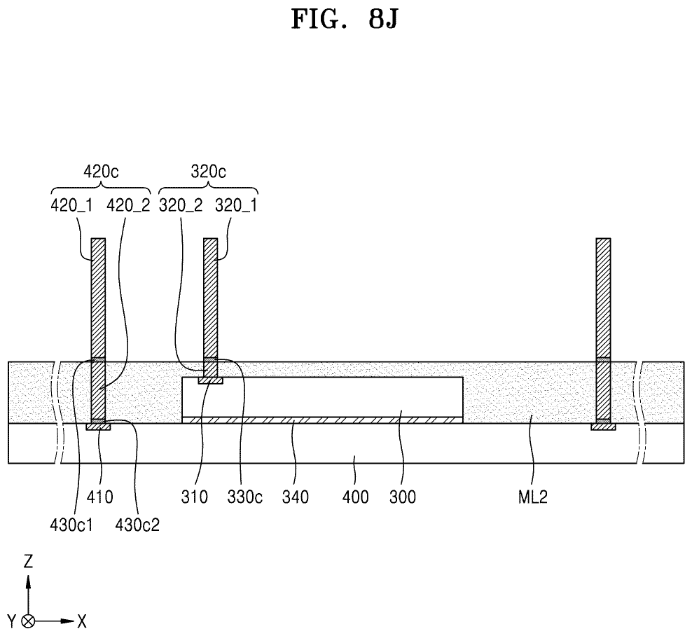

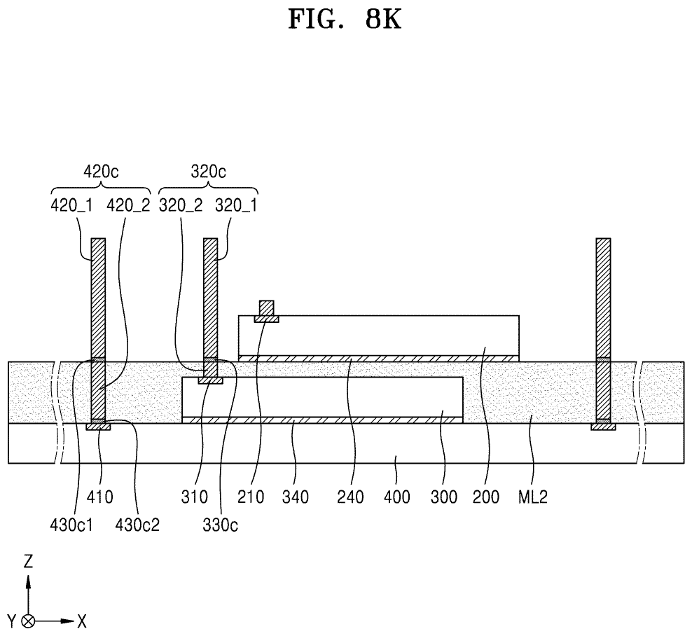

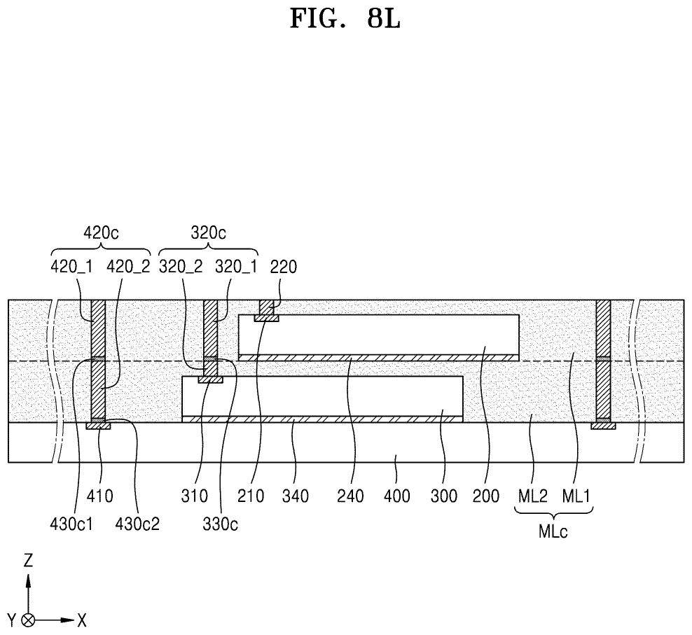

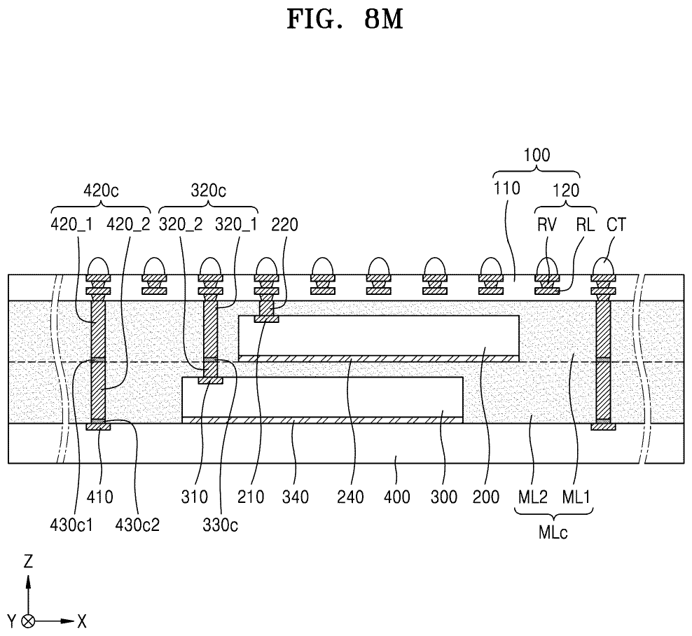

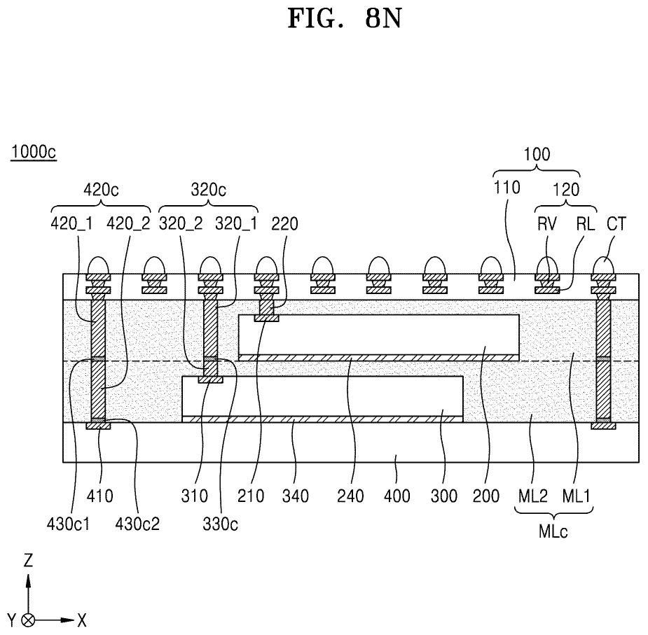

FIGS. 8A to 8N are diagrams illustrating a manufacturing method of a semiconductor package 1000c according to a process sequence, according to an embodiment.

Referring to FIGS. 8A to 8N, a first semiconductor chip 200 and a second semiconductor chip 300 may be stacked on a third semiconductor chip 400 without a separate carrier substrate to fabricate the semiconductor package 1000c.

Referring to FIGS. 8A to 8D, a plurality of second upper conductive posts 420_2 may be formed on the third semiconductor chip 400.

Referring to FIG. 8A, the third semiconductor chip 400 may be prepared in a wafer state before being diced into individual semiconductor chips. The third semiconductor chip 400 may be arranged such that a plurality of third input/output terminals 410 located on the active surface of the third semiconductor chip 400 face upward in the vertical direction (Z direction). Thereafter, a seed layer SD1 may be formed on the top surface of the third semiconductor chip 400. The seed layer SD1 may be conformally formed on the top surface of the third semiconductor chip 400.

Referring to FIG. 8B, a first photoresist PR1 may be formed to cover the top surface of the seed layer SD1. Referring to FIG. 8C, a plurality of first trenches TR1 extending from the top surface to the bottom surface of the first photoresist PR1 may be formed through a photo process. The plurality of first trenches TR1 may be located above the plurality of third input/output terminals 410 of the third semiconductor chip 400. Accordingly, portions of the seed layer SD1 located on the top surfaces of the plurality of third input/output terminals 410 may be exposed to the outside through the plurality of first trenches TR1.

Referring to FIG. 8D, through an electrolytic plating process, the interior of each of the plurality of first trenches TR1 may be filled with a conductive material to form a plurality of second upper conductive posts 420_2. For example, in the electrolytic plating process, the plurality of first trenches TR1 may be filled with the conductive material with the seed layer SD1 as a starting point.

Thereafter, the first photoresist PR1 and a portion of the seed layer SD1 may be removed. For example, a portion of the seed layer SD1 located below the first photoresist PR1 may be removed and a second seed layer 430c2 located below each of the plurality of second upper conductive posts 420_2 may remain. The bottom surface of the second seed layer 430c2 and the top surface of the third semiconductor chip 400 may be coplanar.

Referring to FIG. 8E, the second semiconductor chip 300 may be mounted on the third semiconductor chip 400. For example, in the process of fabricating the second semiconductor chip 300, the plurality of first upper conductive posts 320_2 may be attached to the plurality of second input/output terminals 310 of the second semiconductor chip 300. For example, the second semiconductor chip 300 may be mounted on the third semiconductor chip 400 with the plurality of upper first conductive posts 320_2 attached to the second semiconductor chip 300.

For example, the second semiconductor chip 300 may be mounted on the third semiconductor chip 400 such that the plurality of second input/output terminals 310 located on the active surface of the second semiconductor chip 300 face upward in the vertical direction (Z direction). For example, the second semiconductor chip 300 may be mounted on the third semiconductor chip 400 so as to be spaced apart from the plurality of second upper conductive posts 420_2. The second semiconductor chip 300 may be fixed to the third semiconductor chip 400 through the second adhesive layer 340.

Referring to FIG. 8F, a second molding layer ML2 covering the top surface of the third semiconductor chip 400 and surrounding the plurality of second upper conductive posts 420_2, the second semiconductor chip 300, and the plurality of first upper conductive posts 320_2 may be formed.

Referring to FIGS. 8G to 8J, the plurality of second lower conductive posts 420_1 and the plurality of first lower conductive posts 320_1 may be fabricated on the second molding layer ML2. For example, by fabricating the plurality of second conductive posts 420c through two electrolytic plating processes, the quality of the plurality of second conductive posts 420c may be improved.

Referring to FIG. 8G, a portion of the second molding layer ML2 may be removed such that the top surfaces of the plurality of first upper conductive posts 320_2 are exposed through a polishing process. Accordingly, top surfaces of the plurality of first upper conductive posts 320_2, top surfaces of the plurality of second upper conductive posts 420_2, and a top surface of the second molding layer ML2 may be coplanar. The second semiconductor chip 300 may be located inside the second molding layer ML2.

The seed layer SD2 may cover the top surfaces of the plurality of first upper conductive posts 320_2, the top surfaces of the plurality of second upper conductive posts 420_2, and the top surface of the second molding layer ML2.

Referring to FIG. 8H, a second photoresist PR2 may be formed to cover the second molding layer ML2. Referring to FIG. 8I, a plurality of second trenches TR2 extending from the top surface to the bottom surface of the second photoresist PR2 may be fabricated through a photo process. The plurality of second trenches TR2 may be located above the plurality of second upper conductive posts 420_2 and the plurality of first upper conductive posts 320_2.

Referring to FIG. 8J, through an electrolytic plating process, the interior of each of the plurality of second trenches TR2 may be filled with a conductive material to form the plurality of second lower conductive posts 420_1 and the plurality of first lower conductive posts 320_1. For example, in the electrolytic plating process, the plurality of first trenches TR1 may be filled with the conductive material with the seed layer SD2 as a starting point.

Thereafter, the second photoresist PR2 and a portion of the seed layer SD2 may be removed. For example, a portion of the seed layer SD2 located below the second photoresist PR2 may be removed and a third seed layer 430cl located between the plurality of second lower conductive posts 420_1 and the plurality of second upper conductive posts 420_2 and a first seed layer 330c located between the plurality the first lower conductive posts 320_1 and the plurality of first upper conductive posts 320_2 may remain. The bottom surface of the first seed layer 330c and the bottom surface of the third seed layer 430cl may be coplanar with the top surface of the second molding layer ML2.

The plurality of second lower conductive posts 420_1 and the plurality of second upper conductive posts 420_2 may be collectively referred to as the plurality of second conductive posts 420c and the plurality of first lower conductive posts 320_1 and the plurality of first upper conductive posts 320_2 may be collectively referred to as the plurality of first conductive posts 320c.

Referring to FIG. 8K and FIG. 8L, after the first semiconductor chip 200 is mounted on the second molding layer ML2, the first molding layer ML may be formed. The first semiconductor chip 200 may be offset from the second semiconductor chip 300. For example, the first semiconductor chip 200 may be mounted on the second molding layer ML2 such that the plurality of first input/output terminals 210 located on the active surface of the first semiconductor chip 200 face upward in the vertical direction (Z direction). For example, the second molding layer ML2 may be located between the first semiconductor chip 200 and the second semiconductor chip 300.

The first semiconductor chip 200 may be stacked on the second molding layer ML2 so as to be spaced apart from the plurality of first conductive posts 320c and the plurality of second conductive posts 420c. For example, the first semiconductor chip 200 may be attached to the second molding layer ML2 through the first adhesive layer 240 located on the bottom surface of the first semiconductor chip 200.

For example, the plurality of conductive pillars 220 may be located on the plurality of first input/output terminals 210 of the first semiconductor chip 200. For example, the plurality of conductive pillars 220 may be attached to the first semiconductor chip 200 in the process of manufacturing the first semiconductor chip 200. That is, with the plurality of conductive pillars 220 attached to the first semiconductor chip 200, the first semiconductor chip 200 may be attached to the second molding layer ML2.

In some embodiments, the length of the plurality of conductive pillars 220 in the vertical direction (Z direction) may be about 5 μm to about 40 μm. In some embodiments, there may be no separate seed layer between the plurality of conductive pillars 220 and the plurality of first input/output terminals 210.

Thereafter, the first molding layer ML1, which is located on the second molding layer ML2, may be formed to cover the first semiconductor chip 200, the plurality of second lower conductive posts 420_1, the plurality of first lower conductive posts 320_1, and the plurality of conductive pillars 220. For example, the first molding layer ML1 and the second molding layer ML2 may be collectively referred to as a molding layer MLc. In some embodiments, there may be no interface between the first molding layer ML1 and the second molding layer ML2.

Thereafter, a portion of the first molding layer ML1 may be removed through the polishing process to expose to the outside the top surfaces of the plurality of conductive pillars 220, the top surfaces of the plurality of first conductive posts 320c, and the top surfaces of the plurality of second conductive posts 420. Accordingly, the top surfaces of the plurality of conductive pillars 220, the top surfaces of the plurality of first conductive posts 320c, the top surfaces of the plurality of second conductive posts 420c, and the top surface of the first molding layer ML1 may be coplanar.

Referring to FIG. 8M, the redistribution structure 100 may be formed on the molding layer MLc. The redistribution patterns 120 of the redistribution structure 100 may be in contact with the plurality of first conductive posts 320c, the plurality of second conductive posts 420c, and the plurality of conductive pillars 220. Accordingly, the first semiconductor chip 200, the second semiconductor chip 300, and the third semiconductor chip 400 may be electrically connected to the redistribution structure 100. For example, the external connection terminals CT may be attached to the top surface of the redistribution structure 100. In some embodiments, the width of the redistribution via RV of the redistribution pattern 120 of the redistribution structure 100 may narrow downward in the vertical direction (Z direction).

Referring to FIG. 8N, the resultant of FIG. 8M may be diced into multiple pieces. The resultant of FIG. 8N may be diced into multiple pieces through processes, such as blade dicing, laser dicing, and stellar dicing. Accordingly, the side surface of the third semiconductor chip 400, the side surface of the molding layer MLc, and the side surface of the redistribution structure 100 may be coplanar.

While the inventive concept has been particularly shown and described with reference to embodiments thereof, it will be understood that various changes in form and details may be made therein without departing from the scope of the following claims.

What is claimed is:

1. A semiconductor package comprising:
a redistribution structure comprising a redistribution pattern and a redistribution insulating layer surrounding the redistribution pattern;
a first semiconductor chip above the redistribution structure;
a second semiconductor chip on, and offset relative to, the first semiconductor chip;
a plurality of first conductive posts extending from a bottom surface of the second semiconductor chip to a top surface of the redistribution structure, wherein the plurality of first conductive posts are spaced apart from the first semiconductor chip;
a third semiconductor chip on the second semiconductor chip;
a plurality of second conductive posts extending from a bottom surface of the third semiconductor chip to the top surface of the redistribution structure, wherein the plurality of second conductive posts are spaced apart from the first semiconductor chip and the second semiconductor chip; and
a molding layer between the top surface of the redistribution structure and the bottom surface of the third semiconductor chip, wherein the molding layer surrounds the first semiconductor chip, the second semiconductor chip, the plurality of first conductive posts, and the plurality of second conductive posts.

2. The semiconductor package of claim 1, wherein a side surface of the third semiconductor chip, a side surface of the molding layer, and a side surface of the redistribution structure are coplanar.

3. The semiconductor package of claim 1, wherein an area of a top surface of the third semiconductor chip is equal to an area of the top surface of the redistribution structure, and wherein the area of the top surface of the third semiconductor chip is greater than an area of a top surface of the second semiconductor chip.

4. The semiconductor package of claim 3, wherein a length of the third semiconductor chip in a first direction is greater than a length of the second semiconductor chip in the first direction, and
wherein a length of the third semiconductor chip in a second direction perpendicular to the first direction is greater than a length of the second semiconductor chip in the second direction.

5. The semiconductor package of claim 3, wherein the area of the top surface of the third semiconductor chip is 1.5 to 2 times the area of the top surface of the second semiconductor chip.

6. The semiconductor package of claim 1, wherein a number of the second conductive posts is greater than a number of the first conductive posts.

7. The semiconductor package of claim 6, wherein the number of the second conductive posts is twice the number of the first conductive posts.

8. The semiconductor package of claim 1, wherein the redistribution pattern of the redistribution structure comprises a redistribution line and a redistribution via protruding from the redistribution line in a third direction, and
wherein a width of the redistribution via decreases along the third direction as the redistribution via approaches the first semiconductor chip.

9. The semiconductor package of claim 1, wherein a length of each of the plurality of second conductive posts in a third direction is equal to a length of the molding layer in the third direction, and
wherein a top surface of the third semiconductor chip and side surfaces of the third semiconductor chip are exposed.

10. The semiconductor package of claim 1, further comprising a plurality of conductive pillars on a bottom surface of the first semiconductor chip,
wherein the first semiconductor chip is spaced apart from the redistribution structure in a third direction,
wherein the plurality of conductive pillars extend from the bottom surface of the first semiconductor chip to the top surface of the redistribution structure, and
wherein the molding layer surrounds the plurality of conductive pillars.

11. The semiconductor package of claim 10, wherein a bottom surface of each of the plurality of conductive pillars, a bottom surface of each of the plurality of first conductive posts, a bottom surface of each of the plurality of second conductive posts, and a bottom surface of the molding layer are coplanar.

12. The semiconductor package of claim 1, further comprising:
a first seed layer on a top surface of each of the plurality of first conductive posts; and
a second seed layer on a top surface of each of the plurality of second conductive posts.

13. The semiconductor package of claim 1, further comprising:
a fourth semiconductor chip on, and offset relative to, the second semiconductor chip; and
a third conductive post extending from a bottom surface of the fourth semiconductor chip to the top surface of the redistribution structure, wherein the third semiconductor chip is on the fourth semiconductor chip and the molding layer.

14. A semiconductor package comprising:
a redistribution structure comprising a redistribution pattern and a redistribution insulating layer surrounding the redistribution pattern;
a first semiconductor chip on the redistribution structure;
a plurality of conductive pillars extending from a bottom surface of the first semiconductor chip to a top surface of the redistribution structure;
a first molding layer on the redistribution structure, wherein the first molding layer surrounds the first semiconductor chip and the plurality of conductive pillars;
a second semiconductor chip above the first molding layer and offset relative to the first semiconductor chip;
a plurality of first conductive posts extending from a bottom surface of the second semiconductor chip to the top surface of the redistribution structure, wherein the plurality of first conductive posts are spaced apart from the first semiconductor chip;
a third semiconductor chip on the second semiconductor chip;
a plurality of second conductive posts extending from a bottom surface of the third semiconductor chip to the top surface of the redistribution structure, wherein the plurality of second conductive posts are spaced apart from the first semiconductor chip and the second semiconductor chip; and
a second molding layer between a top surface of the first molding layer and the bottom surface of the third semiconductor chip, wherein the second molding layer surrounds the second semiconductor chip, a portion of each of the plurality of first conductive posts, and a portion of each of the plurality of second conductive posts.

15. The semiconductor package of claim 14, further comprising:
a first seed layer inside each of the plurality of first conductive posts;
a second seed layer on a top surface of each of the plurality of second conductive posts; and
a third seed layer inside each of the plurality of second conductive posts,
wherein a side surface of the first seed layer is coplanar with a side surface of each of the plurality of first conductive posts, and
wherein a side surface of the third seed layer is coplanar with a side surface of each of the plurality of second conductive posts.

16. The semiconductor package of claim 15, wherein a distance between a top surface of the first seed layer and the top surface of the redistribution structure is equal to a distance between a top surface of the third seed layer and the top surface of the redistribution structure.

17. The semiconductor package of claim 15, wherein a top surface of the first seed layer, a top surface of the third seed layer, and the top surface of the first molding layer are coplanar.

18. The semiconductor package of claim 14, wherein the first semiconductor chip and the second semiconductor chip are spaced apart from each other, and
wherein a portion of the second molding layer is between the first semiconductor chip and the second semiconductor chip.

19. A semiconductor package comprising:
a redistribution structure comprising a redistribution pattern and a redistribution insulating layer surrounding the redistribution pattern;
a first semiconductor chip above the redistribution structure;
a plurality of conductive pillars extending from a bottom surface of the first semiconductor chip to a top surface of the redistribution structure;
a first adhesive layer on a top surface of the first semiconductor chip;
a second semiconductor chip above the first semiconductor chip and offset relative to the first semiconductor chip;
a plurality of first conductive posts extending from a bottom surface of the second semiconductor chip to the top surface of the redistribution structure, wherein the plurality of first conductive posts are spaced apart from the first semiconductor chip;
a second adhesive layer on a top surface of the second semiconductor chip;
a third semiconductor chip on the second semiconductor chip, wherein the third semiconductor chip comprises a top surface having an area equal to an area of the top surface of the redistribution structure;
a plurality of second conductive posts extending from a bottom surface of the third semiconductor chip to the top surface of the redistribution structure, wherein the plurality of second conductive posts are spaced apart from the first semiconductor chip and the second semiconductor chip; and
a molding layer between the top surface of the redistribution structure and the bottom surface of the third semiconductor chip, wherein the molding layer surrounds the first semiconductor chip, the second semiconductor chip, the plurality of conductive pillars, the plurality of first conductive posts, and the plurality of second conductive posts,
wherein a side surface of the redistribution structure, a side surface of the molding layer, and a side surface of the third semiconductor chip are coplanar, and
wherein a number of the second conductive posts is greater than a number of the first conductive posts.

20. The semiconductor package of claim 19, further comprising:
a first seed layer inside each of the plurality of first conductive posts;
a second seed layer on a top surface of each of the plurality of second conductive posts; and
a third seed layer inside each of the plurality of second conductive posts,
wherein a distance between a top surface of the first seed layer and the top surface of the redistribution structure is equal to a distance between a top surface of the third seed layer and the top surface of the redistribution structure.
